(19) United States
(12) Patent Application Publication
(10) Pub. No.: US 2024/0429359 A1
(43) Pub. Date: Dec. 26, 2024

(54) MICRO LED PACKAGE, DISPLAY HAVING SAME, AND METHOD FOR MANUFACTURING DISPLAY

(71) Applicant: KOREA PHOTONICS TECHNOLOGY INSTITUTE, Gwangju (KR)

(72) Inventors: Tak JEONG, Gwangju (KR); Jun Beom PARK, Jangseong-gun (KR)

(21) Appl. No.: 18/701,697

(22) PCT Filed: Oct. 5, 2022
(86) PCT No.: PCT/KR2022/014971

§ 371 Date: Apr. 16, 2024

(30) Foreign Application Priority Data
Dec. 21, 2021 (KR) 10-2021-0183960
Dec. 21, 2021 (KR) 10-2021-0183961
Aug. 1, 2022 (KR) 10-2022-0095267

(51) Int. Cl. H01L 33/62; H01L 25/16; H01L 33/00

(52) U.S. Cl. CPC H01L 33/62; H01L 25/167; H01L 33/0093; H01L 2933/0066

(57) ABSTRACT

The present invention relates to a micro LED package, a display having the same, and a method for manufacturing the display and, more specifically, to a micro LED package, a display having the same, and a method for manufacturing the display, in which a plurality of micro LEDs having different colors are packaged in a single pixel unit or a plurality of pixel units to facilitate connection to a driving connection electrode unit of the display. In the micro LED package and the display having the same according to the present invention, even if the size of the micro LED chips becomes small, the driving connection electrode unit of the display may be easily connected to the display driving connection electrode unit without rearranging or redesigning the driving connection electrode unit of the display, thereby making it possible to utilize the driving connection electrode unit of the existing display.

### TECHNICAL FIELD

The present invention relates to a micro LED package, a display having the same, and a method for manufacturing the display and, more specifically, to a micro LED package, a display having the same, and a method for manufacturing the display, in which a plurality of micro LEDs having different colors are packaged in a single pixel unit or a plurality of pixel units to facilitate connecting to a driving connection electrode unit of the display. This study was conducted with the support of the Ministry of Trade, Industry and Energy's material and component technology development project (project number: 20004946) and the display innovation process platform construction project (project number: 20010690).

### BACKGROUND TECHNOLOGY

The micro LED display has self-luminous characteristics, and is superior in terms of reaction speed, brightness, color reproducibility, and low power driving characteristics when compared with the OLED having the same self-luminous characteristics. The micro LED display is more advantageous in application to a mobile display because it has high durability and lifespan due to the characteristics of an inorganic material element. In addition, due to the characteristics of micro LEDs, the micro LEDs can be assembled in a module type, and thus the micro LEDs can be applied even to ultra-high-definition large-sized displays.

From the viewpoint of commercialization of micro LEDs, productivity, process cost, transfer success rate, large area process, high integration, and coupling compatibility with the backplane as well as the possibility of mass transfer should be verified.

In order to implement a micro LED display, a process of arranging a plurality of micro LED chips at regular intervals and mounting individual micro LED chips on a driving connection electrode unit of the display is essential.

However, the size of the micro LED chip is reduced under the development of the technology, the electrode size of the micro LED chip is also reduced, and thus the problem of rearranging or redesigning the driving connection electrode unit of the display on which the micro LED chip is mounted comes up. Further, it is very difficult to precisely mount the micro LED chip on the driving connection electrode unit of the display. Accordingly, it is required to develop more precise material and equipment embodying high-degree accuracy.

### DETAILED DESCRIPTION OF THE INVENTION

### Technical Problems

The present invention has been made in an effort to resolve the problems of the prior arts to provide a micro LED package capable of easily connecting micro LED chips to a display driving connection electrode unit without rearranging or redesigning the driving connection electrode unit of a display even when a size of the micro LED chips becomes small.

Another object of the present invention is to provide a micro LED package and a display having the same, in which micro LED chips can be easily connected to a display driving connection electrode unit without developing materials and equipment having high precision even if the size of the micro LED chips becomes small.

In addition, another object of the present invention is to provide a method for manufacturing a display in which a micro LED chip having a defect is replaced on a temporary substrate before the micro LED chip is transferred to a main substrate, thereby easily replacing the defective chip and shortening a manufacturing process.

Another object of the present invention is to provide a display and a method of manufacturing the display capable of preventing a disconnection of a wiring layer near an interface between a micro LED chip and a passivation layer during a curing process of the passivation layer.

### Technical Solution

To achieve these and other advantages and in accordance with the purpose of the invention, there is provided a micro LED package including: a temporary substrate; a plurality of micro LED chips arranged on the temporary substrate; a first passivation layer formed to enclose the micro LED chips; a plurality of first wiring layers each having one side connected to electrodes of each of the micro LED chips and the other side extending along the first passivation layer; a second passivation layer formed to enclose upper portions of the first wiring layers and spaces between the first wiring layers; and a plurality of second wiring layers each having one side connected to the first wiring layer through the second passivation layer and the other side extending along the second passivation layer.

The number of the second wiring layers of the micro LED package according to the present invention may be less than the total number of electrodes of the micro LED chips included in the micro LED package.

According to an aspect of the present invention, there is provided a display including: a main substrate having a driving connection electrode portion provided on one surface thereof; a plurality of micro LED packages including a plurality of micro LED chips, wiring portions connected to and rearranged with electrodes of the micro LED chips, respectively, and a passivation layer insulating the wiring portions, the plurality of micro LED packages being mounted on the main substrate to configure a single pixel or a plurality of pixels on the main substrate; and a connection relay portion interconnecting the wiring portion and the driving connection electrode portion of each of the micro LED packages, wherein the micro LED packages are transferred to the main substrate in a state in which the plurality of micro LED chips, the passivation layer, and the wiring portions are packaged on a temporary substrate.

The micro LED package of the display according to the present invention comprises: a plurality of micro LED chips arranged to be spaced apart from each other horizontally at regular intervals; a first passivation layer formed to surround the micro LED chips; a plurality of first wiring layers having one side connected to electrodes of each of the micro LED chips and the other side extending along the first passivation layer; a second passivation layer formed to surround an upper portion of the first wiring layers and between the first wiring layers; and a plurality of second wiring layers having one side connected to the first wiring layer through the second passivation layer and the other side extending along the second passivation layer.

The first passivation layer of the display according to the present invention may be formed to have a height lower than one surface on which the electrode of the micro LED chip is formed, and the first wiring layer may include a first horizontal wiring portion extending to surround an upper surface of the first passivation layer, a vertical wiring portion extending from the first horizontal wiring portion around the micro LED chip to surround side surfaces of the micro LED chip, and a second horizontal wiring portion extending from the vertical wiring portion to surround the upper surface and the electrode of the micro LED chip together.

The first passivation layer of the display according to the present invention may include a first flat portion formed to have a height lower than one surface on which the electrode of the micro LED chip is formed, and a first protruded portion protruded to surround the electrode and one surface on which the electrode of the micro LED chip is formed around the micro LED chip, and the first wiring layer may include a first horizontal wiring portion extending to surround an upper surface of the first flat portion, a first vertical wiring portion extending from the first horizontal wiring portion to surround a side surface of the first protruded portion, a second horizontal wiring portion extending from the first vertical wiring portion to surround an upper surface of the first protruded portion, and a second vertical wiring portion extending from the second horizontal wiring portion to surround an upper surface of the electrode of the micro LED chip.

According to the another aspect of the present invention, a black matrix may be disposed on the first passivation layer of the display device.

The number of the second wiring layers of the display according to the present invention may be less than the total number of the electrodes of the micro LED chips included in the micro LED package.

A display manufacturing method according to an embodiment of the present invention comprises: a first transferring step of transferring a micro LED chip formed on a growth substrate to be arranged on a first surface of a temporary substrate; an inspection step of inspecting the micro LED chip transferred on the temporary substrate; a replacing step of removing the defective micro LED chip selected in the inspection step from the temporary substrate and then replacing the defective micro LED chip with a non-defective micro LED chip; a fixing step of fixing the micro LED chip on the temporary substrate to the temporary substrate; a wiring step of forming a wiring portion on the micro LED chip fixed on the temporary substrate; and a second transferring step of transferring only the micro LED chip from the temporary substrate to a main substrate functioning as a backplane, wherein the wiring step includes: a first passivation layer forming step of forming a first passivation layer to surround the first surface of the temporary substrate and the micro LED chip together; a photoresist layer forming step of forming a photoresist layer on the first passivation layer on the micro LED chip to have a larger area than the micro LED chip; a first etching step of etching and removing a part of the first passivation layer; a photoresist layer removing step of removing the photoresist layer; a second etching step of etching and removing a part of the first passivation layer to expose the entire electrode and the upper surface of the micro LED chip; a first wiring layer forming a first wiring layer and a first passivation layer to be electrically connected to the electrode of the micro LED; and a first passivation layer; and a first passivation layer; and a first passivation layer forming the first passivation layer forming the first passivation layer; and a first passivation layer forming the first passivation layer; and a second passivation layer forming the first passivation layer; and a part of the first passivation layer of the first passivation layer of the first passivation layer of the first passivation layer; a third etching step of etching and removing a portion of the second passivation layer; and a second wiring layer forming step of forming a second wiring layer on the second passivation layer so as to be electrically connected to the first wiring layer.

In the second etching step of the method of manufacturing a display according to an embodiment of the present disclosure, the first passivation layer may be removed such that a distance between an upper surface of the micro LED chip and an upper surface of the first passivation layer is smaller than a thickness of the first wiring layer, in order to prevent the first wiring layer from being disconnected near an interface between the first passivation layer and the micro LED chip while the first passivation layer is deformed during curing.

According to another embodiment of the present invention, the second wiring layer may include a second anode wiring layer formed on the second passivation layer to be exposed and connected to the first connection electrode of the main substrate, and a second cathode wiring layer formed on the second passivation layer to be exposed and connected to the second connection electrode of the main substrate.

In the display manufacturing method according to an embodiment of the present invention, the second transferring step may include a connecting step of electrically connecting a main substrate functioning as a backplane on the second wiring layer, and a separating step of separating the micro LED chip and the first passivation layer from the temporary substrate after irradiating laser beams toward an interface between the temporary substrate and the micro LED chip and an interface between the temporary substrate and the first passivation layer for a predetermined time at the temporary substrate side so as to weaken or release a bonding force between the micro LED chip and the temporary substrate.

According to another aspect of the present invention, there is provided a method of manufacturing a display, the method including: transferring a micro LED chip formed on a growth substrate to be disposed on a first surface of a temporary substrate; inspecting the micro LED chip transferred to the temporary substrate; removing the defective micro LED chip selected in the inspecting step from the temporary substrate and then replacing the defective micro LED chip with a non-defective micro LED chip; fixing the micro LED chip on the temporary substrate to the temporary substrate; forming a wiring portion on the micro LED chip fixed to the temporary substrate; and transferring only the micro LED chip from the temporary substrate to a main substrate functioning as a backplane, wherein the wiring includes: a first passivation layer forming step of forming a first passivation layer to surround the first surface of the temporary substrate and the micro LED chip; a photoresist layer forming step of forming, on the first passivation layer on the micro LED chip, a photoresist layer having an opening part with an area smaller than an area of an upper surface of the micro LED chip so that an area of the photoresist layer is larger than an area of the micro LED chip and a surface of the first passivation layer is exposed to a central portion corresponding to the micro LED chip; a first etching step of etching to remove the photoresist layer and removing a portion of the first passivation layer so that the first passivation layer is exposed to the outside; and the first passivation layer and the first passivation layer are electrically connected; and the first passivation layer; and the first passivation layer; a second passivation layer forming step of forming a second passivation layer on the first wiring layer; a third etching step of etching and removing a portion of the second passivation layer to expose a portion of an upper surface of the first wiring layer of the micro LED chip; and a second wiring layer forming step of forming a second wiring layer on the second passivation layer to be electrically connected to the first wiring layer.

In the second etching step of the method for manufacturing a display according to another embodiment of the present invention, the first passivation layer may be removed such that a distance between an upper surface of the micro LED chip and an upper surface of the first passivation layer is smaller than a thickness of the first wiring layer, in order to prevent the first wiring layer from being disconnected near an interface between the first passivation layer and the micro LED chip while the first passivation layer is deformed during curing process.

The second wiring layer may include a second anode wiring layer formed on the second passivation layer to be exposed and connected to the first connection electrode of the main substrate, and a second cathode wiring layer formed on the second passivation layer to be exposed and connected to the second connection electrode of the main substrate.

The second transferring step may include: a connecting step of electrically connecting a main substrate functioning as a backplane to the second wiring layer; and a separating step of separating the micro LED chip and the first passivation layer from the temporary substrate after irradiating laser beams toward an interface between the temporary substrate and the micro LED chip and an interface between the temporary substrate and the first passivation layer at the temporary substrate side for a predetermined time so as to weaken or release a bonding force between the micro LED chip and the temporary substrate.

According to another aspect of the present invention, there is provided a method of manufacturing a display, the method including: a first transferring step of transferring a micro LED chip formed on a growth substrate so that the micro LED chip is disposed on a first surface of a temporary substrate; an inspecting step of inspecting the micro LED chip transferred on the temporary substrate; a replacing step of removing a defective micro LED chip selected in the inspecting step from the temporary substrate and then replacing the defective micro LED chip with a non-defective micro LED chip; a fixing step of fixing the micro LED chip on the temporary substrate to the temporary substrate; a wiring step of forming a wiring portion on the micro LED chip fixed to the temporary substrate; and a second transferring step of transferring only the micro LED chip from the temporary substrate to a main substrate functioning as a backplane, wherein the wiring step includes: a first passivation layer forming step of forming a first passivation layer so as to enclose the first surface of the temporary substrate and the micro LED chip together; a first photoresist layer forming step of forming a first photoresist layer on the first passivation layer on an upper side of the micro LED chip so that the first photoresist layer has a larger area than the micro LED chip; a first etching step of etching and removing a part of the first photoresist layer; a first photoresist layer removing step of removing the first photoresist layer and forming a photoresist layer on the first passivation layer on the first passivation layer on the first passivation layer on the micro LED chip so that a surface of forming a surface of the micro UV chip has a smaller area than the micro LED and a surface area of the micro LED is exposed, and a surface of the micro LED is exposed The method may include: a second etching step of etching and removing a portion of the first passivation layer to expose an electrode and a central portion of an upper surface to the outside; a second photoresist layer removing step of removing the second photoresist layer; a third etching step of etching and removing a portion of the first passivation layer; a first wiring layer forming step of forming a first wiring layer to be electrically connected to an electrode of the micro LED chip; a second passivation layer forming step of forming a second passivation layer on the first passivation layer and the first wiring layer; a fourth etching step of etching and removing a portion of the second passivation layer to expose a portion of an upper surface of the first wiring layer of the micro LED chip; and a second wiring layer forming step of forming a second wiring layer to be electrically connected to the first wiring layer on the second passivation layer.

In the third etching step of the method for manufacturing a display according to still another embodiment of the present invention, the first passivation layer may be removed such that a distance between an upper surface of the micro LED chip and an upper surface of the first passivation layer is smaller than a thickness of the first wiring layer in order to prevent the first wiring layer from being disconnected near an interface between the first passivation layer and the micro LED chip while the first passivation layer is deformed during curing process.

The second wiring layer may include a second anode wiring layer formed on the second passivation layer to be exposed and connected to the first connection electrode of the main substrate, and a second cathode wiring layer formed on the second passivation layer to be exposed and connected to the second connection electrode of the main substrate.

The second transferring step may include: a connecting step of electrically connecting a main substrate functioning as a backplane on the second wiring layer; and a separating step of separating the micro LED chip and the first passivation layer from the temporary substrate after irradiating laser beams toward an interface between the temporary substrate and the micro LED chip and an interface between the temporary substrate and the first passivation layer on the temporary substrate side for a predetermined time so as to weaken or release a bonding force between the micro LED chip and the temporary substrate.

### Effects of the Invention

In the micro LED package and the display having the same according to the present invention, even if the size of the micro LED chips becomes small, the micro LED chips could be easily connected to the display driving connection electrode unit without rearranging or redesigning the driving connection electrode unit of the display, thereby making it possible to utilize the existing driving connection electrode unit of the display.

In addition, in the micro LED package and the display having the same according to the present invention, even if the size of the micro LED chip is reduced, the micro LED chips are easily connected to the driving connection electrode unit of the display through the rearranged wiring unit without developing materials and equipment having high precision, thereby reducing manufacturing costs and solving various technical difficulties that may occur in a existing mounting process of the micro LED chip.

In addition, in the display according to the present invention, the number of electrodes of the micro LED package connected to the driving connection electrode unit of the display may be reduced compared to the total number of electrodes of the micro LED chip included in the micro LED package, and the electrode area of the micro LED package connected to the driving connection electrode unit of the display may be increased, thereby more stably and reliably connecting the micro LED package to the driving connection electrode unit of the display.

### BRIEF DESCRIPTION OF DRAWINGS

FIG. 1 is a view illustrating a micro LED package according to an embodiment of the present disclosure and a display having the same.

FIG. 2 is a view illustrating the micro LED package shown in FIG. 1.

FIG. 3 is a view illustrating a micro LED package according to another exemplary embodiment of the present invention.

FIG. 4 is a view illustrating a micro LED package according to another exemplary embodiment of the present invention.

FIGS. 5 to 12 are views illustrating a process of manufacturing a micro LED package according to the present invention and a process of manufacturing a display by transferring the manufactured micro LED package to a main board.

FIG. 13 is a plan view of a micro LED package according to an embodiment.

FIG. 14 is a plan view of a micro LED package according to another embodiment.

FIGS. 15 to 27 are views illustrating a method of manufacturing a display according to another embodiment of the present invention.

FIGS. 28 to 40 are views illustrating a method of manufacturing a display according to another embodiment of the present invention.

FIGS. 41 to 56 are views illustrating a method of manufacturing a display according to another embodiment of the present invention.

### BEST MODE FO THE INVENTION

Hereinafter, a micro LED package according to a preferred embodiment of the present invention and a display having the same will be described in detail with reference to the accompanying drawings.

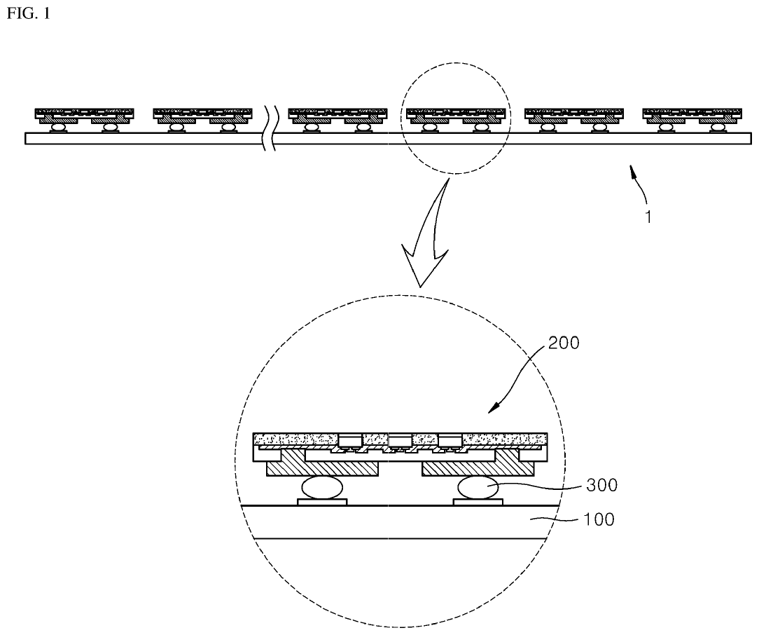

In FIGS. 1 to 4 illustrate a display 1 according to an embodiment of the present invention. Referring to FIGS. 1 to 4, the display 1 according to the present invention may include a main substrate 100, a plurality of micro LED packages 200, and a connection relay unit 300.

The main substrate 100 is a backplane and may include a thin film transistor (TFT) or a PCB. Here, the thin film transistor may include a circuit unit having a gate electrode, an active layer electrically insulated from the gate electrode by a gate insulating layer, a source electrode electrically and a drain electrode connected to the active layer. In addition, a driving connection electrode unit including a plurality of first main connection electrodes 101 and a plurality of second main connection electrodes 102 connected to the TFTs is formed on a bottom surface of the main substrate 100 to be exposed.

The micro LED package 200 (hereinafter, “package 200”) is mounted on the main substrate 100 through the connection relay unit 300 and the first main connection electrode 101 and the second main connection electrode 102 of the main substrate 100.

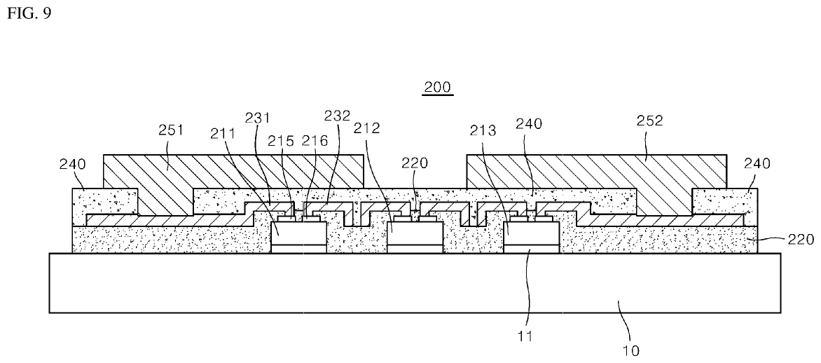

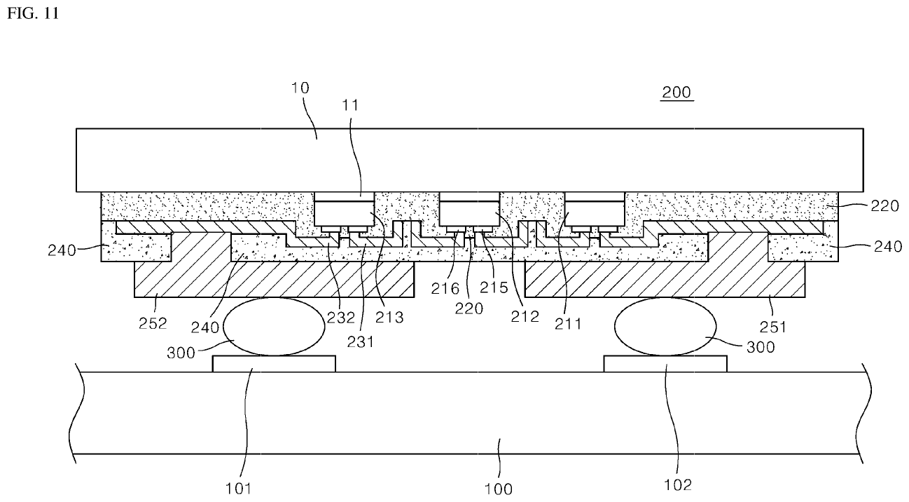

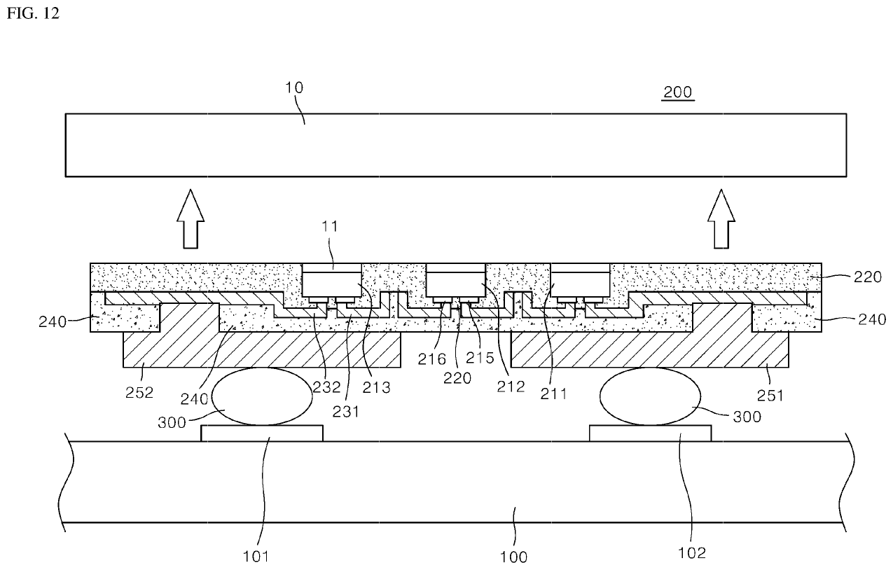

Referring to FIGS. 1 to 2 and 9 to 12, the package 200 includes a temporary substrate 10, micro LED chips 211, 212, and 213, a passivation layer including a first passivation layer 220 and a second passivation layer 240, and a wiring portion including rearranged first and second wiring layers. The package 200 is manufactured in a form in which the temporary substrate 10 is provided, and the temporary substrate 10 may be removed after the package 200 is mounted on the main substrate 100.

According to the present invention, the package 200 in a state in which packaging is completed, is transferred to the main board 100. In other words, unlike the conventional display in which individual micro LED chips are mounted on the main substrate 100 and then packaged through a protective film process as necessary, the display according to the present invention has a structure in which the micro LED package 200 that has been packaged is mounted on the main substrate 100 after the packaging process is completed by sequentially stacking the micro LED chips 211, 212, and 213, the first passivation layer 220, the first wiring layer, the second passivation layer 240, and the second wiring layer on the temporary substrate 10.

The package 200 according to the present disclosure includes three micro LED chips 211, 212, and 213. The three micro LED chips 211, 212, and 213 are composed of R, G, and B, respectively. The three microchips 211, 212, and 213 including R, G, and B are horizontally arranged adjacent to each other at a predetermined interval to form a single pixel.

The package 200 shown in the drawings includes only three microchips of Red (R), Green (G), and Blue (B) so that each package 200 configures a single pixel on the main board 100. Alternatively, each package 200 may include a plurality of micro LED chips so as to configure a plurality of pixels on the main board 100. Here, the package 200 including the plurality of pixels may be configured by integrally forming at least two pixels, each of which includes only the three microchips 211, 212, and 213 of R, G, and B.

The micro LED chips 211, 212, and 213 applied to the package 200 may have a thickness of 10 um or less and a size of 100 um or less.

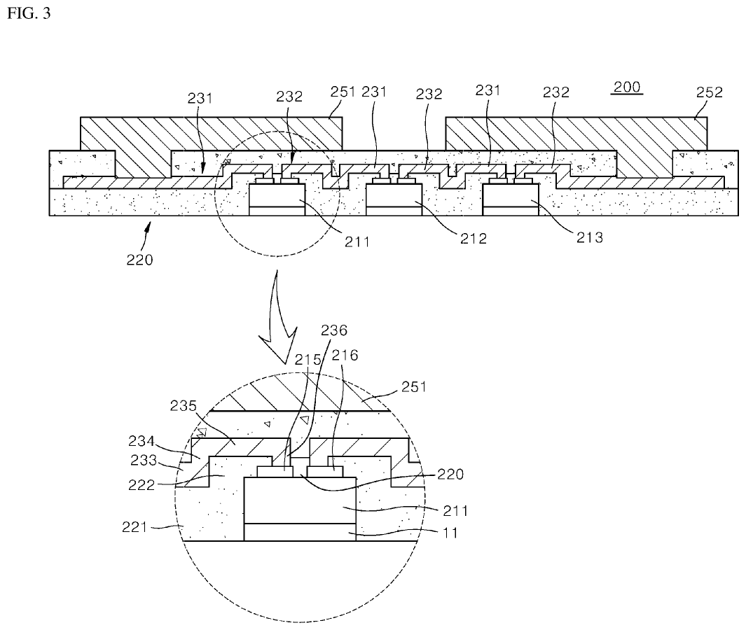

The first passivation layer 220 may be formed to surround the plurality of micro LED chips 211, 212, and 213. More specifically, as illustrated in FIG. 3, the first passivation layer 220 is formed to occupy side surfaces of the micro LED chips 211, 212, and 213, upper surfaces of the micro LED chips 211, 212, and 213 on which the positive electrodes 215 and the negative electrodes 216 are formed, and partial portions of the positive electrodes 215 and the negative electrodes 216 of the micro LED chips 211, 212, and 213. In addition, the first passivation layer is formed to occupy a space between the positive electrode 215 and the negative electrode 216 of the micro LED chip, respectively, thereby insulating the positive electrode 215 and the negative electrode 216 of each micro LED chip from each other.

Differently from that shown, the first passivation layer 220 may be formed to occupy only the upper surfaces of the micro LED chips 211, 212, and 213 except for the positive electrode 215 and the negative electrode 216.

The first passivation layer 220 is formed to have a height lower than the upper surface of the positive electrode 215 and the negative electrode 216 of the micro LED chips 211, 212, and 213, and thus, a step is formed between the upper surface of the first passivation layer 220 and the upper surface of the micro LED chips 211, 212, and 213. In addition, the step between the micro LED chips 211, 212, and 213 and the first passivation layer 220 may be formed to be thinner than a thickness of a first wiring layer to be described hereinafter. That is, the first wiring layer may be formed to be thicker than the step.

The first passivation layer 220 may be formed of an insulating material, for example, acryl, poly (methyl methacrylate) (PMMA), benzocyclobutene (BCB), polyimide, acrylate, epoxy, a photoresist material, polyester, or the like.

Meanwhile, although not shown in the drawings, a black matrix for improving visibility of different colors emitted from the micro LED chips 211, 212, and 213 and increasing a contrast ratio of the display may be formed on the first passivation layer 220. In this case, the black matrix may be formed in the remaining region except for the micro LED chip.

One side of the first wiring layer is connected to the electrodes of each of the micro LED chips 211, 212, and 213, and the other side thereof extends along the first passivation layer 220.

More specifically, the first wiring layer includes the plurality of first anode wiring layers 231 connected to the positive electrode 215 of each of the micro LED chips 211, 212, and 213 and the plurality of first cathode wiring layers 232 connected to the negative electrode 216 of each of the micro LED chips 211, 212, and 213.

The second passivation layer 240 may be formed to surround upper portions of the first wiring layers and spaces between the first wiring layers, thereby insulating the first wiring layers from each other.

Like the first passivation layer described above, the second passivation layer 240 may be formed of acryl, poly (methyl methacrylate) (PMMA), benzocyclobutene (BCB), polyimide, acrylate, epoxy, a photoresist material, polyester, or the like.

The second passivation layer 240 is provided with a hole penetrating therethrough in order to electrically connect the second wiring layer to the first wiring layer. The hole may be formed by etching a portion of the second passivation layer 240 in a process of manufacturing the package 200.

One side of the second wiring layer passes through the second passivation layer 240 and is connected to the first wiring layer, and the other side thereof extends along the second passivation layer 240. The second wiring layer is inter-connected to the first wiring layer by filling a hole 241 formed in the second passivation layer 240 while surrounding an upper surface of the second passivation layer 240.

The second wiring layer may include a second anode wiring layer 251 inter-connected to the first anode wiring layer 231 and a second cathode wiring layer 252 inter-connected to the first cathode wiring layer 232.

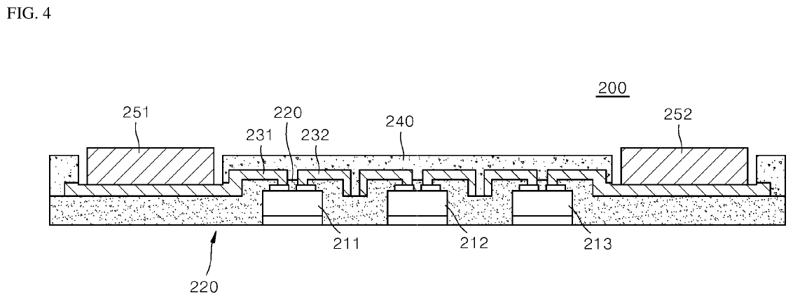

In addition, as shown in FIG. 4, the second wiring layer may have a structure in which it is inter-connected to the first wiring layer by filling only the hole 241 formed in the second passivation layer 240 without extending on the upper surface of the second passivation layer 240.

In the display 1 according to the present invention, the second wiring layer formed in the package 200 is connected to the driving connection electrode portions 101 and 102 by the connection relay portion 300.

The connection relay unit 300 inter-connects each of the wiring portion of the packages 200 and the driving connection electrode 101 and 102 to each other, and may be a bonding material such as a metal solder bump, a stud bump, a vertical conductive film, an anisotropic conductive film (ACF), or an anisotropic conductive adhesive (ACA). In addition, a eutectic bonding method using a metal thin film having a low melting point may be applied.

As described above, the first passivation layer 220 of the display 1 according to the present embodiment may be formed to have a height lower than the surface on which the electrodes of the micro LED chips 211, 212, and 213 are formed.

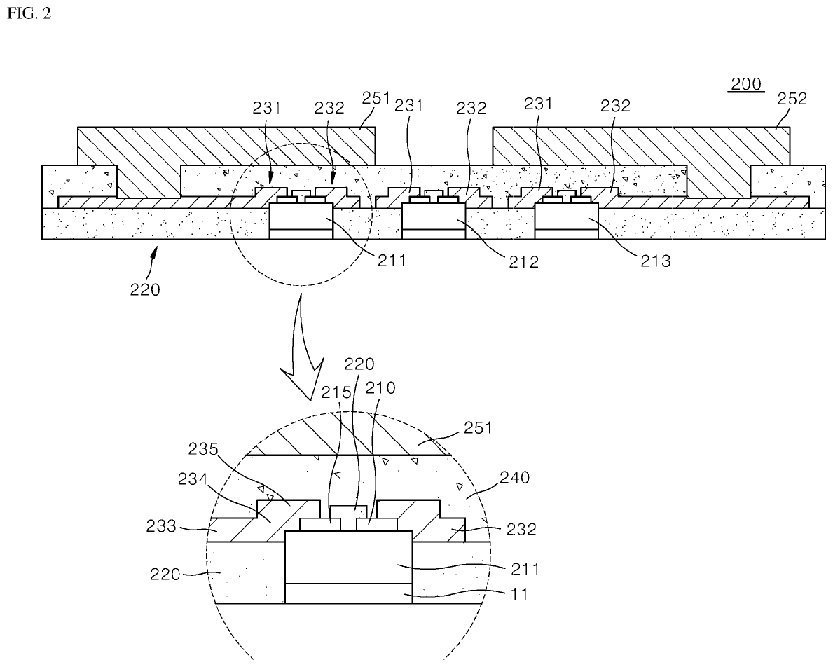

As shown in FIG. 2, the first wiring layer may include a first horizontal wiring portion 233, a vertical wiring portion 234, and a second horizontal wiring portion 235.

The first horizontal wiring portion 233 extends to surround an upper surface of the first passivation layer 220. The vertical wiring portion 234 extends from the first horizontal wiring portion 233 around the micro LED chips 211, 212, and 213 to surround side surfaces of the micro LED chips 211, 212, and 213.

The second horizontal wiring portion 235 extends from the vertical wiring portion 234 to surround the upper surfaces and the electrodes of the micro LED chips 211, 212, and 213 together.

The first horizontal wiring portion 233, the vertical wiring portion 234, and the second horizontal wiring portion 235 may be integrally formed to be thicker than a step between the upper surfaces of the micro LED chips 211, 212, and 213 and the first passivation layer 220 in order to prevent breaking of wire.

In the display 1 as described above, the height of the first passivation layer 220 may be formed to be lower than the height of the upper surfaces of the micro LED chips 211, 212, and 213 or the height of the positive electrode 215 and the negative electrode 216, and the thickness of the first wiring layer may be formed to be thicker than the interval between the first passivation layer 220 and the upper surfaces of the micro LED chips 211, 212, and 213, thereby preventing the first wiring layer from being disconnected at the boundary between the micro LED chips 211, 212, and 213 and the first passivation layer 220.

Alternatively, the first passivation layer 220 may include a first flat portion 221 and a first protruded portion 222.

Referring to FIG. 3, the first flat portion 221 is formed to have a height lower than the surface on which the electrodes of the micro LED chips 211, 212, and 213 are formed. The first protruded portion 222 is protruded so as to surround one surface of LED chips 211, 212, and 213 on which the electrodes are formed and a partial portion of the electrodes around the micro LED chips 211, 212, and 213.

According to the structural change of the first passivation layer 220, the first wiring layer may include a first horizontal wiring portion 233, a first vertical wiring portion 234, a second horizontal wiring portion 235, and a second vertical wiring portion 236.

The first horizontal wiring portion extends to surround an upper surface of the first flat portion 221.

The first vertical wiring portion 234 extends from the first horizontal wiring portion 233 to surround a side surface of the first protruded portion 222.

The second horizontal wiring portion 235 extends from the first vertical wiring portion 234 to surround the upper surface of the first protruded portion 222.

The second vertical wiring portion 236 extends from the second horizontal wiring portion 235 to surround the upper surfaces of the electrodes of the micro LED chips 211, 212, and 213.

In the display 1 as described above, by forming the first passivation layer 220 at a level slightly higher than or equal to the electrodes and the upper surfaces of the micro LED chips 211, 212, and 213 on the edge portions of the upper surfaces of the micro LED chips 211, 212, and 213, it is possible to effectively prevent a phenomenon in which the first passivation layer 220 surrounding the side surfaces of the micro LED chips 211, 212, and 213 is spaced apart from the side surfaces of the micro LED chips 211, 212, and 213, or the first passivation layer 220 surrounding the upper surfaces of the micro LED chips 211, 212, and 213 is spaced apart from the upper surfaces of the micro LED chips 211, 212, and 213, and thus, the first wiring layer formed thereon is floated and disconnected.

In the display according to the present embodiment, the total number of the second anode wiring layer 251 and the second cathode wiring layer 252 exposed to the outside of the package by the rearranged wiring portions, that is, the first wiring layer and the second wiring layer, is less than the total number of the electrodes of the micro LED chips 211, 212, and 213 included in the corresponding package.

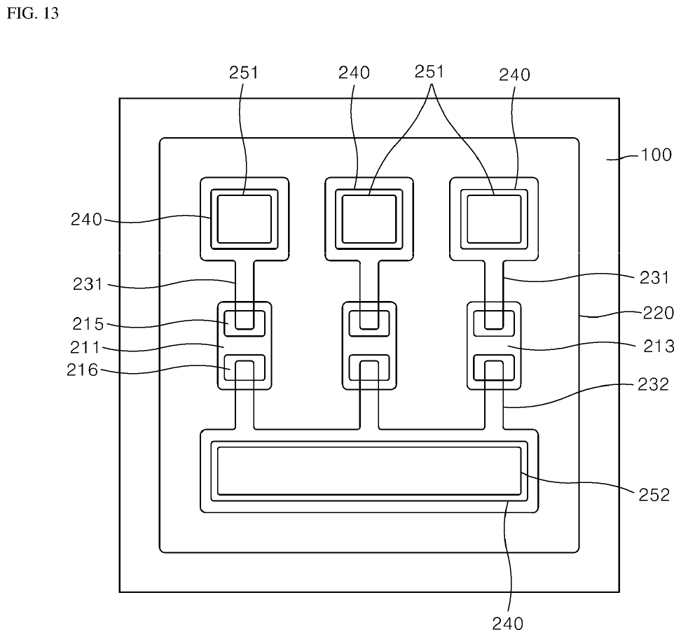

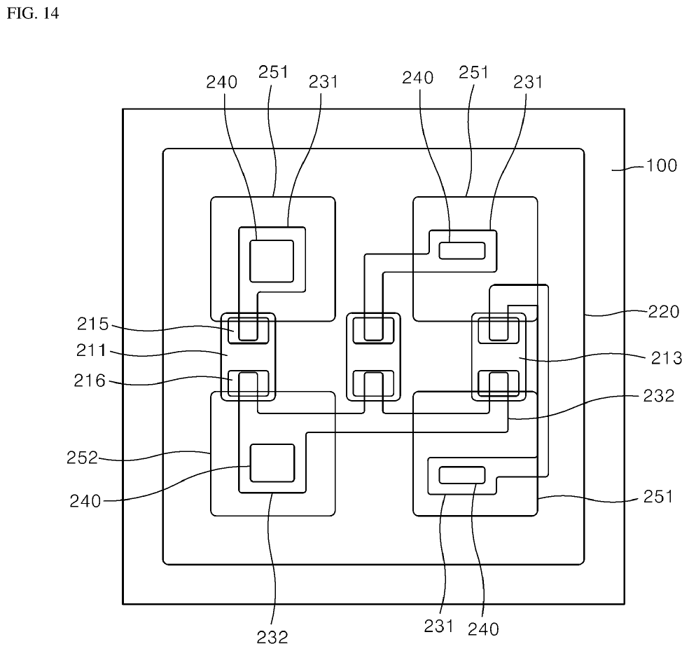

Referring to FIGS. 13 and 14, when three R, G, and B micro LED chips are applied, the package may have a total of six micro LED chip electrodes (three positive electrodes 215 and three negative electrodes 216). The three negative electrodes 216 are commonly connected to the rearranged first negative electrode wiring layer 232 and second negative electrode wiring layer 252, and the three positive electrodes 215 are connected to the rearranged three first positive electrode wiring layer 231 and second positive electrode wiring layer 251, respectively, thereby reducing the number of second wiring layers of the package 200 connected to the driving connection electrode portions 101 and 102 of the main substrate 100 to four (4).

In the structure shown in FIGS. 13 and 14 by applying the package 200 configured with a single pixel using three R, G, and B LED chips, six (6), which is the total number of electrodes of the micro LED chips included in the package 200 is reduced to four (4), which is the number of the second wiring layers of the package 200. However, in the structure wherein the number of micro LED chips is increased so as to configure a plurality of pixels in one package 200, the number of the second wiring layers may be further reduced.

For example, when two pixels are configured in one package 200, six (6) micro LED chips are provided in the corresponding package 200, and in this case, the total number of electrodes of the micro LED chips is 12 (twelve). As described above, when the six (6) positive electrodes 231 of the micro LED chip are inter-connected to the six (6) second positive electrode wiring layers 251, respectively, and the six (6) negative electrodes 232 of the micro LED chip are inter-connected to the only one (1) second negative electrode wiring layer 252, the total number of the second wiring layers of the package finally formed through the rearrangement becomes seven (7). That is, 12 wiring layers may be reduced to 7 wiring layers.

In addition, in the display according to the present embodiment, an arrangement structure of the second positive electrode wiring layer 251 and the second negative electrode wiring layer 252 of the package 200 may be formed in various patterns.

Referring to FIG. 13, three (3) second cathode wiring layers 251 may be formed side by side on one side of the package 200, and one (1) second anode wiring layer 252 parallel to the arrangement direction of the second cathode wiring layers 251 and having a relatively long length may be formed on the other side of the package.

Alternatively, the second cathode wiring layer 251 and the second anode wiring layer 252 may be uniformly distributed and arranged in the package 200 as illustrated in FIG. 14.

Referring to FIG. 14, the second cathode wiring layer 251 and the second anode wiring layer 252 having the same size may be distributed and arranged at four corners of the package 200, thereby forming the second wiring layer having a relatively larger area than the second wiring layer illustrated in FIG. 13. In addition, the connection area between the package and the connection relay unit are increased by the second wiring layer having the increased area, thereby, the connection between the package 200 and the main substrate 100 becomes to be more stable and reliable

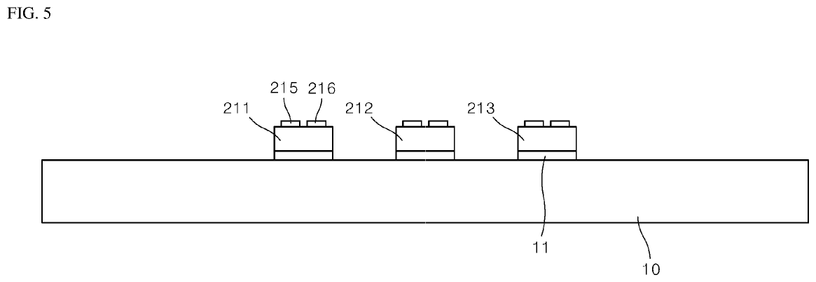

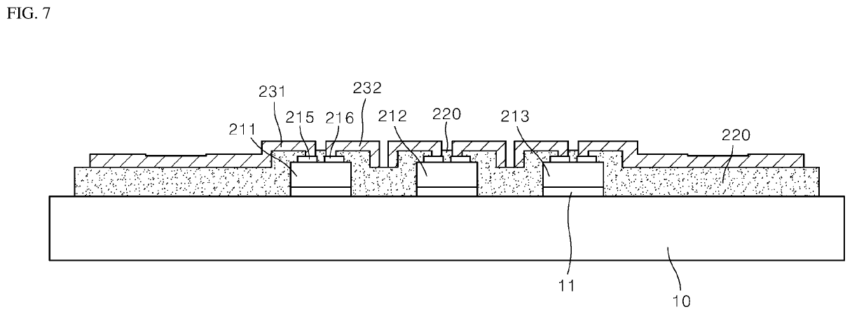

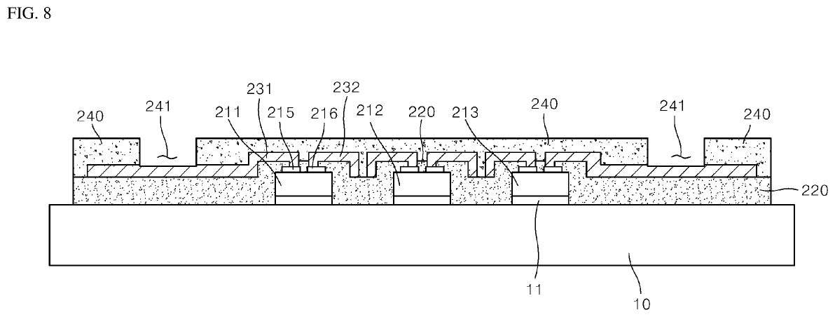

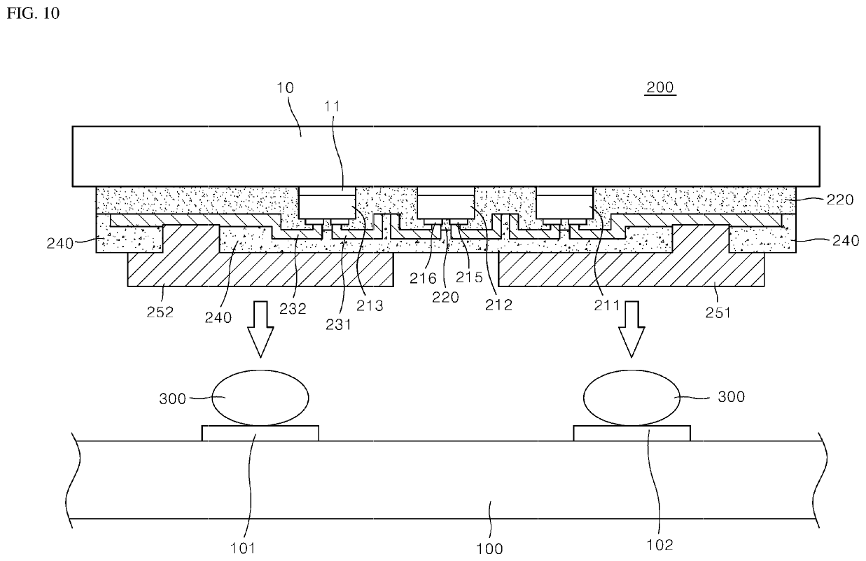

FIGS. 5 to 9 illustrate a process of manufacturing a package according to the present invention, and FIGS. 10 to 12 illustrate a process of manufacturing the display 1 using the package.

The package 200 illustrated in FIGS. 1 and 2 may be manufactured through the manufacturing process of the package 200 illustrated in FIGS. 5 to 9. The display 1 illustrated in FIG. 1 may be manufactured through the process illustrated in FIGS. 10 to 12 by using the package 200 manufactured through the process illustrated in FIGS. 5 to 9.

Referring to FIGS. 5 to 9, a process of manufacturing a package 200 may largely include a temporary substrate 10 preparation step of preparing the temporary substrate 10 on which the adhesive layer 11 is provided, a first transfer step of transferring three different micro LED chips 211, 212, and 213 emitting light of different colors to be disposed on the temporary substrate 10, and a wiring step of forming a rearranged wiring portion on the micro LED chips 211, 212, and 213 transferred to the temporary substrate 10.

In the first transferring step, the R, G, and B micro LED chips 211, 212, and 213 are disposed on one surface of the temporary substrate 10 to be spaced apart from each other at a predetermined interval. A releasing layer may be formed on one surface of the temporary substrate 10 to facilitate separation of the package 200 in a separation step to be described later. An adhesive layer 11 may be provided between the releasing layer and the temporary substrate 10. The releasing layer and the adhesive layer 11 may be removed in a separation step to be described later. The temporary substrate 10 may be formed of a transparent material to transmit light. For example, it may be formed of any one material of glass, sapphire, PET, or PI.

The wiring step includes forming a first passivation layer 220, forming a first wiring layer, forming a second passivation layer 240, and forming a second wiring layer.

In the step of forming of the first passivation layer 220, the first passivation layer 220 is formed so as to surround the first surface of the temporary substrate 10 and the side surfaces, portions of the upper surfaces the micro LED chips 211, 212 and 213 and portions of the electrodes of the micro LED chips 211, 212 and 213. The first passivation layer formed on the upper surface of the micro LED chip is preferably formed so as to insulate the positive electrode 215 and the negative electrode 216 of the micro LED chips 211, 212 and 213.

The step of forming of the first passivation layer 220 may further include forming a black matrix between the micro LED chips in order to improve visibility of different colors emitted from the micro LED chips 211, 212, and 213, respectively, and to increase a contrast ratio of the display.

In the step of forming of the first wiring layer, a first anode wiring layer 231 and a first cathode wiring layer 232 are formed on the first passivation layer 220 to be electrically connected to the positive electrode 215 and the negative electrode 216 of the micro LED chips 211, 212, and 213, respectively.

In the step of forming of the second passivation layer 240, the second passivation layer 240 is formed on the first passivation layer 220 and the first wiring layer. In this case, the second passivation layer 240 is formed on the upper surface of the first wiring layer to insulate between the first positive-electrode wiring layer 231 and the first positive-electrode wiring layer 232.

After the step of forming of the second passivation layer 240, a portion of the second passivation layer 240 may be etched and removed to expose a portion of the first wiring layer to the outside of the second passivation layer 240, thereby forming a hole 241.

In the step of forming of the second wiring layer, the second wiring layer is formed to be electrically connected to the first wiring layer through the hole 241 formed in the second passivation layer 240. The second wiring layer may extend to occupy the area of the hole 241 formed in the second passivation layer 240 and the upper surface of the second passivation layer 240 as illustrated, or may be formed only in the area of the hole 241.

After the step of forming of the second wiring layer is completed, the manufacturing of the micro LED package 200 according to the present invention is completed.

The micro LED package 200 according to the present invention may include the temporary substrate 10 as needed, or may be in a form in which the temporary substrate 10 is removed.

A process of manufacturing a display according to an embodiment of the present invention is illustrated in FIGS. 10 to 12. Referring to FIGS. 10 to 12, a process of manufacturing the display 1 may largely include a bonding step and a separating step.

In the bonding step, the connection relay unit 300 including ACA, ACF, or solder is applied or disposed on the driving connection electrode units 101 and 102 provided on the main board 100, and the package 200 is turned over so that the second wiring layer could face the driving connection electrode units 101 and 102 of the main board 100, thereby bonding and fixing the second wiring layer of the package 200 to the connection relay unit 300.

After the package 200 is bonded to the main board 100, the temporary board 10 is separated from the package 200 in the separation step. In the separating step, the releasing layer or the adhesive layer provided on the temporary substrate 10 may be separated from the first passivation layer 220 by irradiating laser or light to the rear surface of the temporary substrate 10. Through this step, transfer of the package 200 onto the main substrate 100 and manufacturing of the display are completed.

The temporary substrate 10 may be formed of a transparent or translucent material. The display 1 may be configured by including the temporary substrate 10 without the separation step, if necessary.

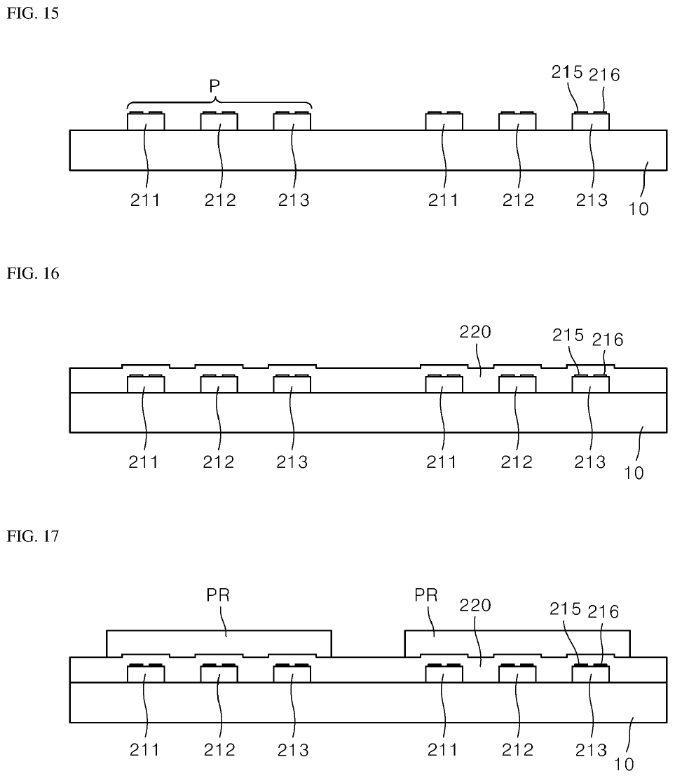

Meanwhile, a method of manufacturing a display according to another embodiment of the present invention is illustrated in FIGS. 15 to 27. A method of manufacturing a display according to another embodiment of the present invention may include a first transferring step of transferring micro LED chips 211, 212, and 213 formed on a growth substrate to be disposed on one surface of a temporary substrate 10, an inspecting step of inspecting the micro LED chips 211, 212, and 213 transferred to the temporary substrate 10, a replacing step of removing the defective micro LED chips selected in the inspecting step from the temporary substrate 10 and replacing the defective micro LED chips with non-defective micro LED chips, a fixing step of fixing the micro LED chips 211, 212, and 213 to the temporary substrate 10, a wiring step of forming a wiring portion on the micro LED chips 211, 212, and 213 fixed to the temporary substrate 10, and a second transferring step of transferring the micro LED chips 211, 212, and 213 from the temporary substrate 10 onto a main substrate 10 functioning as a backplane.

A display manufacturing process according to another embodiment of the present invention will be described in more detail with reference to FIGS. 15 to 27.

FIG. 15 illustrates a structure in which the micro LED chips 211, 212, and 213 are transferred onto one surface of the temporary substrate 10. Referring to FIG. 15, in the first transfer step, the micro LED chips 211, 212, and 213 are transferred to the temporary substrate 10.

The temporary substrate 10 may be formed of a transparent substrate so that light output from the micro LED chips 211, 212, and 213 is transmitted therethrough. For example, the substrate may be formed of any one material of glass, sapphire, PET, or PI. Various substrates such as a rigid substrate or a flexible substrate may be used as the temporary substrate 10.

The micro LED chips 211, 212, and 213 are used to reproduce colors such as R, G, and B (RED, Green, Blue), and the like, and may be manufactured on the growth substrate. In addition, a positive electrode 215 and a negative electrode 216 are provided on the upper surfaces of the micro LED chips 211, 212, and 213, respectively. The micro LED chips 211, 212, and 213 are arranged adjacent to each other at a predetermined interval so that three (3) micro LED chips 211, 212, and 213 form one pixel P including R, G, and B. The three micro LED chips 211, 212, and 213 reproduce R, G, and B, respectively.

Meanwhile, the micro LED chips 211, 212, and 213 may be adhered and fixed to the temporary substrate 10 by a transparent adhesive layer. That is, before the first transferring step of transferring the micro LED chips 211, 212, and 213 onto the temporary substrate 10, a step of forming a transparent adhesive layer on the temporary substrate 10 may be further included.

The transparent adhesive layer may be patterned on the temporary substrate 10 through a photolithography process. As an example, a transparent adhesive layer may be deposited on one surface of the temporary substrate 10, and the layer of portions on which the micro LED chips 211, 212, and 213 are not disposed may be removed through a plasma etching process.

The transparent adhesive layer may be formed of any one material of Pressure Sensitive Adhesives (PSA), silicon-based material, acrylic-based material, and epoxy. For the transparent adhesive layer, any material may be used as long as it could bond the micro LED chips 211, 212, and 213 to the temporary substrate 10 while being cured in response to heat and UV light. The micro LED chips 211, 212, and 213 are bonded to the temporary substrate 10 by a transparent adhesive layer, and may be bonded by a predetermined adhesive force so that defective micro LED chips selected in the inspection step may be relatively easily separated from the temporary substrate 10. Here, the adhesive force of the transparent adhesive layer may be adjusted by controlling temperature or UV light.

In the inspection step, the micro LED chips 211, 212, and 213 transferred to the temporary substrate 10 are measured using a micro PL or EL measurement method, and whether the micro LED chips 211, 212, and 213 are defective is determined according to the measurement result.

In the replacement step, the defective micro LED chips 211, 212, and 213 selected in the inspection step are removed from the temporary substrate 10 and then replaced with non-defective micro LED chips. The selected defective micro LED chip may be individually or simultaneously removed after the location determination.

The defective micro LED chip may be removed by using laser ablation, an electrostatic chuck, a magnetic chuck, or the like.

In the fixing step, the micro LED chips 211, 212, and 213 are fixed to the temporary substrate 10 by permanently curing the transparent adhesive layer through a heat or UV curing method.

In the wiring step, a wiring portion is formed on all the micro LED chips 211, 212, and 213 fixed on the temporary substrate 10 gone through the fixing step.

The wiring step may include a first passivation layer forming step, a photoresist layer forming step, a first etching step, a photoresist layer removing step, a second etching step, a first wiring layer forming step, a second passivation layer forming step, a third etching step, and a second wiring layer forming step.

FIG. 16 illustrates the first passivation layer forming step.

Referring to FIG. 16, in the forming of the first passivation layer, the first passivation layer 220 is formed to surround one surface of the temporary substrate 10 and the micro LED chips 211, 212, and 213 together. In this case, the first passivation layer 220 preferably surrounds all of the micro LED chips 211, 212, and 213 disposed on the temporary substrate 10. In addition, the first passivation layer 220 may be formed on the entire area of the temporary substrate 10, or may be independently formed for each pixel P region composed of three micro LED chips 211, 212, and 213.

The first passivation layer 220 may be formed of an insulating material, for example, acryl, polymethylmethacrylate (PMMA), benzocyclobutene (BCB), polyimide, acrylate, epoxy, polyester, or the like. Preferably, the first passivation layer 220 may include a material capable of absorbing light, for example, a black matrix. When the black matrix is applied, mixing of colors emitted through the temporary substrate 10 may be prevented.

FIG. 17 illustrated a photoresist layer forming step.

Referring to FIG. 3, in the forming of the photoresist layer, the photoresist layer PR is formed on the first passivation layer 220 above the micro LED chips 211, 212, and 213 so as to have at least a wider area than the area of the micro LED chips 211, 212, and 213. In this case, the photoresist layer PR may be formed in a region corresponding to the first passivation layer 220, or alternatively, may be independently formed only in a portion corresponding to the pixel P region composed of the three micro LED chips 211, 212, and 213. Preferably, the photoresist layer is independently formed only the portion corresponding to the pixel P region so that the first passivation layer 220 on the peripheral of the pixel P region is entirely removed in the first etching step and the second etching step to be described later.

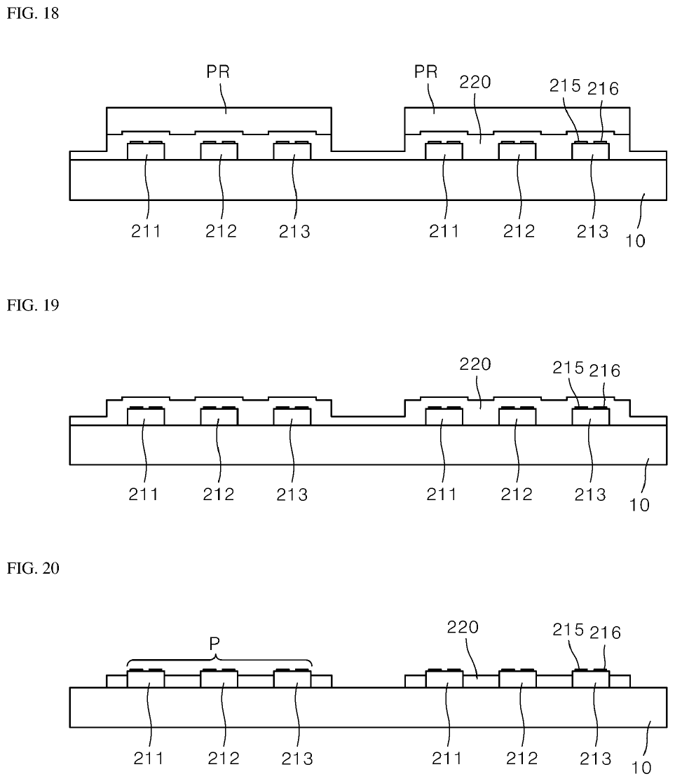

FIG. 18 illustrates a first etching step.

Referring to FIG. 18, in the first etching step, a portion of the first passivation layer 220 is etched and removed. In more detail, in the first etching step, the first passivation layer 220 corresponding to the periphery of the pixel P region, which is an edge region of the first passivation layer 220, is removed by a predetermined thickness, so that a step is generated between the first passivation layer 220 corresponding to the pixel P region and the first passivation layer 220 on peripheral of the pixel P region. In the first etching step, a reactive ion etching (RIE) method may be applied.

In the removing step of the photoresist layer after the first etching, the photoresist layer PR on the first passivation layer 220 is removed so that the first passivation layer 220 is exposed as illustrated in FIG. 19.

FIG. 20 illustrates a second etching step.

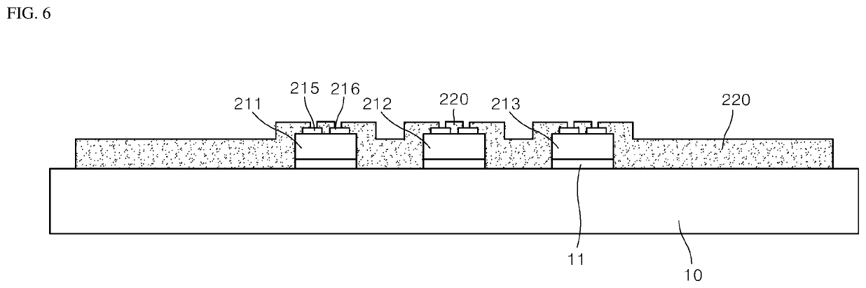

Referring to FIG. 6, in the second etching step, the first passivation layer 220 remaining after the first etching step is etched to a predetermined thickness so that all the electrodes and the upper surfaces of the micro LED chips 211, 212, and 213 are exposed to the outside. In the second etching step, a reactive ion etching (RIE) method may be applied as applied in the first etching step.

In the second etching step, it is preferable to remove the first passivation layer 220 so that the distance between the electrodes of the micro LED chips 211, 212, and 213 or the upper surfaces thereof and the upper surface of the first passivation layer 220 is smaller than the thickness of the first wiring layer to be described later. This is to prevent the first wiring layer from being disconnected near the interface between the first passivation layer 220 and the micro LED chips 211, 212, and 213. This is also to prevent the first passivation layer 220 on the temporary substrate 10 from being deformed while the first passivation layer 220 is being cured after a first wiring layer forming step to be described later.

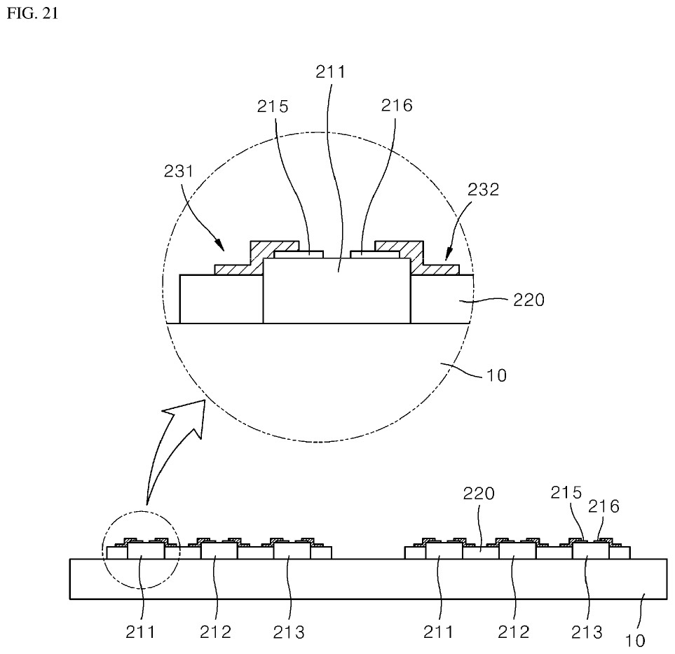

FIG. 21 illustrates a first wiring layer forming step.

Referring to FIG. 21, in the forming of the first wiring layer, after the second etching step is completed, the first wiring layer is formed to be inter-connected to each of the positive electrode 215 and the negative electrode 216 provided on the upper surfaces of the micro LED chips 211, 212, and 213.

The first wiring layer formed in the step of forming the first wiring layer includes a first anode wiring layer 231 inter-connected to the positive electrode 215 of the micro LED chips 211, 212, and 213 and a first cathode wiring layer 232 inter-connected to the negative electrode 216 of the micro LED chips 211, 212, and 213.

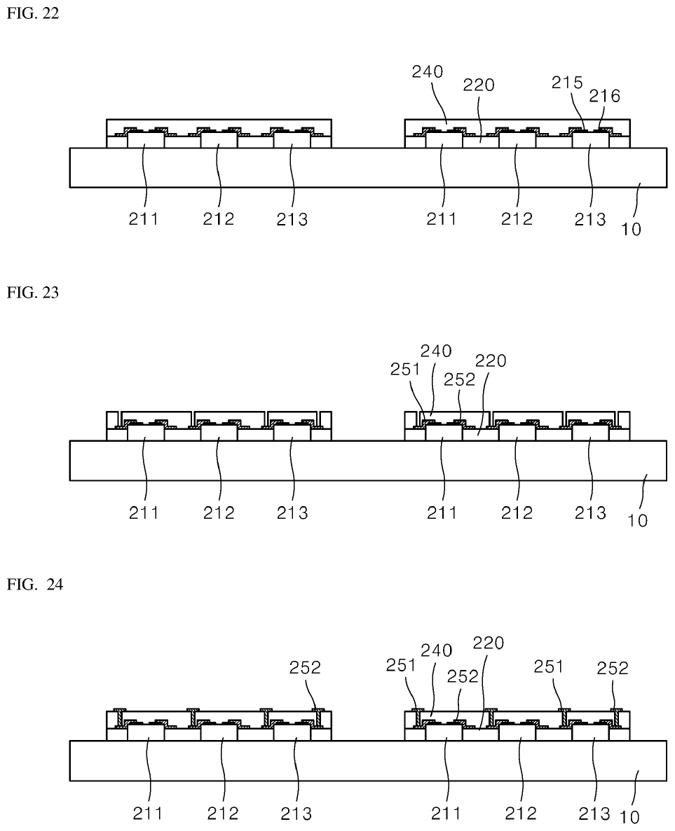

In the step of forming the second passivation layer, as illustrated in FIG. 22, the second passivation layer 240 may be formed to have a predetermined thickness so as to surround the first passivation layer 220 and the first wiring layer together. Here, the second passivation layer 240 may be formed to entirely cover the first wiring layer. The second passivation layer 240 may be formed of, for example, acryl, polymethylmethacrylate (PMMA), benzocyclobutene (BCB), polyimide, acrylate, epoxy, polyester, or the like.

FIG. 23 illustrates a third etching step.

Referring to FIG. 23, in the third etching step, a portion of the second passivation layer 240 is etched and removed so that a portion of the upper surface of the first wiring layer connected to the positive electrode and the negative electrode of the micro LED chips 211, 212, and 213, respectively, is exposed. In the third etching step, vertically penetrating holes are formed in a region of the second passivation layer 240 corresponding to an upper portion of the first wiring layer.

FIG. 24 illustrates a second wiring layer forming step.

Referring to FIG. 24, in the step of forming the second wiring layer, the second wiring layer is formed on the second passivation layer 240 to be electrically connected to the first wiring layer. The second wiring layer formed in the step of forming the second wiring layer is configured to include a conductive material, and extends to be exposed on the surface of the second passivation layer 240 through the hole of the second passivation layer 240.

The second wiring layer may include a second anode wiring layer 251 and a second cathode wiring layer 252. The second anode wiring layer 251 may have one side inter-connected to the first anode wiring layer 231 and may penetrate through the hole of the second passivation layer 240 so that the other side thereof is exposed to the surface of the second passivation layer 240. The second cathode wiring layer 252 may have one side inter-connected to the first anode wiring layer 232, and may penetrates through the hole of the second passivation layer 240 so that the other side thereof is exposed to the surface of the second passivation layer 240.

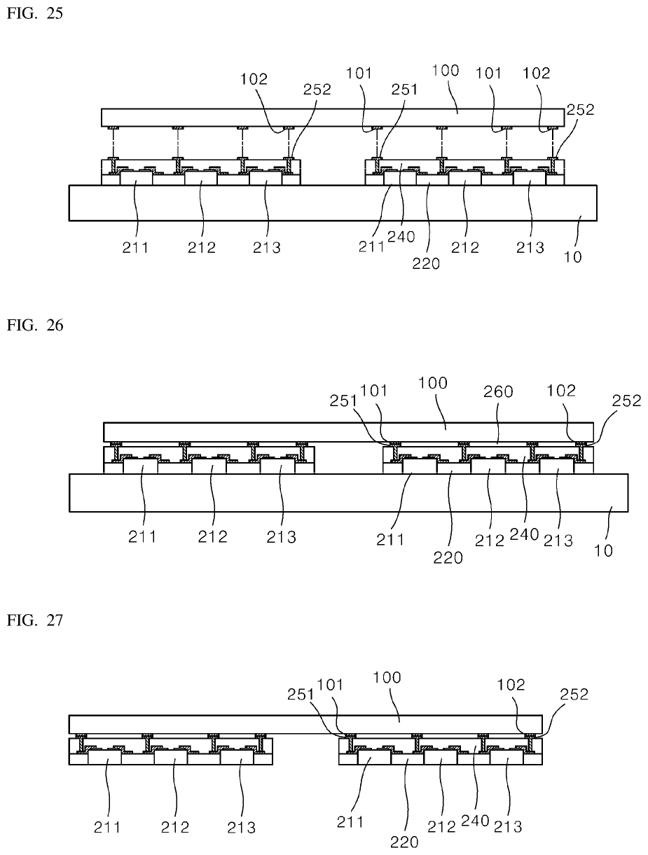

FIG. 25 illustrates a second transferring step.

Referring to FIG. 25, the second transferring step, which is a step of transferring only the packaged micro LED chips 211, 212, and 213 from the temporary substrate 10 onto the main substrate 100 functioning as a backplane, may include a connecting step and a separating step.

In the connection step, the main substrate 100 functioning as a backplane is electrically connected to the second wiring layer including the second anode wiring layer 251 and the second cathode wiring layer 252.

The main substrate 100 is a backplane and may include a thin film transistor (TFT) or a PCB. Here, the thin film transistor may include a circuit unit having a gate electrode, an active layer electrically insulated from the gate electrode by a gate insulating layer, and a source electrode and a drain electrode electrically connected to the active layer. In addition, the driving connection electrode parts 101 and 102 connected to the TFTs are formed to be exposed on the bottom surface of the main substrate 100.

In the main substrate 100, the driving connection electrode portions 101 and 102 may be attached to contact the second anode wiring layers 251 and the second cathode wiring layers 252 of the second wiring layer, respectively. The driving connection electrode portions 101 and 102 may be attached to contact the second anode wiring layers 251 and the second cathode wiring layers 252 by bonding, respectively.

For example, the second anode wiring layer 251 connected to the anode electrode 215 of the micro LED chips 211, 212, and 213 may be connected to the driving connection electrode portions 101 of the main substrate 100, and the second cathode wiring layer 252 connected to the cathode electrode 216 of the micro LED chips 211, 212, and 213 may be connected to the driving connection electrode portions 102 of the main substrate 100. In addition, as a method of attaching the main board 100 to the wiring portions, a bonding material such as a metal solder bump, a stud bump, a vertical conductive film, an anisotropic conductive film (ACF), or an anisotropic conductive adhesive (ACA) may be used.

After the main substrate 100 is attached and connected to the second wiring layer, an underfill process of filling a resin 260 between the second passivation layer 240 or the second wiring layer and the main substrate 100 may be performed as illustrated in FIG. 26.

After the underfill process is completed, the separation step is performed as shown in FIG. 27. The separating step is a step of separating the temporary substrate 10 from the micro LED chips 211, 212, and 213. In order to weaken or release a mutual coupling force or adhesive force between the micro LED chips 211, 212, and 213 and the temporary substrate 10, laser is irradiated from the temporary substrate 10 side toward the interface between the temporary substrate 10 and the micro LED chips 211, 212, and 213 and the interface between the temporary substrate 10 and the first passivation layer 220 for a predetermined time, and then the micro LED chips 211, 212, and 213 and the first passivation layer 220 are separated from the temporary substrate 10. The micro LED package separated from the temporary substrate 10 may be mounted on the main substrate 100, which is the final target substrate, for each pixel.

As described above, in the method of manufacturing a micro LED display according to the present invention, by forming the height of the first passivation layer 220 to be lower than or equal to the upper surfaces of the micro LED chips 211, 212, and 213 or the height of the positive electrode 215 and the negative electrode 216, and by forming the thickness of the first wiring layer to be thicker than the interval between the first passivation layer 220 and the upper surfaces of the micro LED chips 211, 212, and 213, it is possible to prevent the wiring layer from being disconnected near the interfaces between the micro LED chips 211, 212, and 213 and the first passivation layer 220 during the curing process of the first passivation layer 220, and accordingly, the present method provides advantages in that the defect occurrence rate of the micro LED display may be lowered and the yield may be increased.

In addition, the display manufactured by the display manufacturing method according to the present invention is formed such that the second wiring layer connected to the connection electrode of the main board 100 has a relatively larger area than the anode electrode 215 and the cathode electrode 216 of the micro LED chips 211, 212, and 213 through the wiring layer re-arrangement structure. Therefore, alignment accuracy is not required to be connected to the driving connection electrode portions 101 and 102 of the main board 100 or the final target board. Accordingly, the method has an advantage of being very simple and easy to manufacture compared to the prior arts.

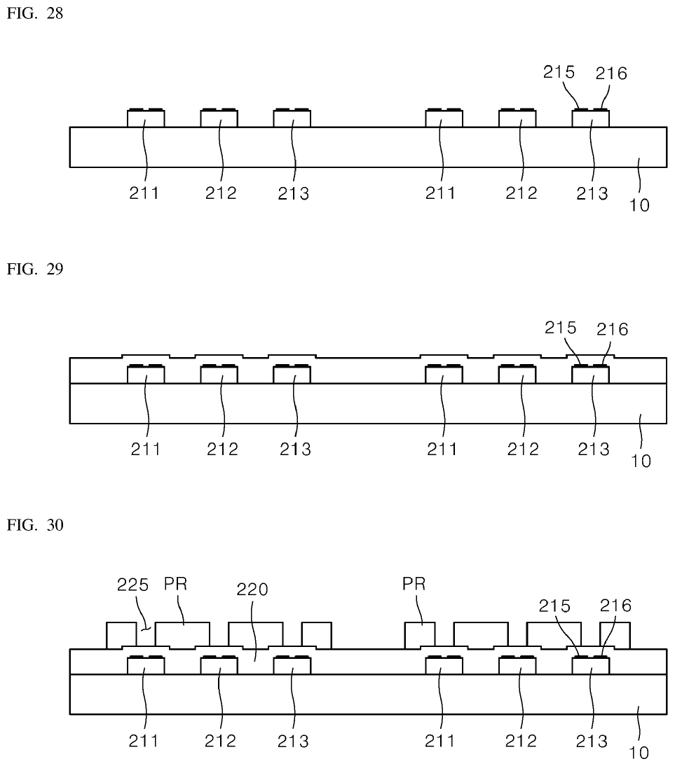

Meanwhile, FIGS. 28 to 40 illustrate a method of manufacturing a display according to another embodiment of the present invention. According to the present embodiment, a method for manufacturing a micro LED display comprises: a first transfer step of transferring micro LED chips 211, 212, 213, which are formed on a growth substrate, so that the micro LED chips are arranged on one surface of a temporary substrate 10; an inspection step of inspecting the micro LED chips 211, 212, 213 which are transferred on the temporary substrate 10; a replacing step of removing defective micro LED chips, which are selected in the inspection step, from the temporary substrate 10 and replacing the defective micro LED chips with non-defective micro LED chips; a fixing step of fixing the micro LED chips on the temporary substrate 10 to the temporary substrate 10; a wiring step of forming a wiring portion on the micro LED chips which are fixed to the temporary substrate 10; and a second transfer step of transferring only the micro LED chips from the temporary substrate 10 onto a main substrate 100 which functions as a backplane.

The method of manufacturing a display according to another embodiment of the present invention uses the same method and process as those of the method of manufacturing a display according to the embodiment of the present invention described with reference to FIGS. 15 to 27 for the first transferring step, the inspection step, the replacement step, the fixing step, and the second transferring step except the wiring step. Detailed descriptions for same steps will be omitted.

FIG. 28 illustrates a structure in which the micro LED chips 211, 212, and 213 are transferred onto one surface of the temporary substrate 10. Referring to FIG. 28, in the first transferring step, the micro LED chips 211, 212, and 213 are transferred to the temporary substrate 10.

In the inspection step, the micro LED chips 211, 212, and 213 transferred onto the temporary substrate 10 are measured using a micro PL or EL measurement method, and whether the micro LED chips 211, 212, and 213 are defective is determined according to the measurement result.

In the replacement step, the defective micro LED chips 211, 212, and 213 selected in the inspection step are removed from the temporary substrate 10 and then replaced with non-defective micro LED chips. The selected defective micro LED chip may be individually or simultaneously removed after the location determination.

In the fixing step, the micro LED chips 211, 212, and 213 on the temporary substrate 10 are fixed to the temporary substrate 10 by permanently curing the transparent adhesive layer through a heat or UV curing method.

In the wiring step after the fixing step, a wiring portion is formed on all the micro LED chips 211, 212, and 213 fixed on the temporary substrate 10.

More specifically, the wiring step may include a first passivation layer forming step, a photoresist layer forming step, a first etching step, a photoresist layer removing step, a second etching step, a first wiring layer forming step, a second passivation layer forming step, a third etching step, and a second wiring layer forming step.

In FIG. 29, a first passivation layer forming step is illustrated.

Referring to FIG. 29, in the forming of the first passivation layer, the first passivation layer 220 is formed to surround one surface of the temporary substrate 10 and the micro LED chips 211, 212, and 213 together. In this case, the first passivation layer 220 may be formed to surround all of the micro LED chips 211, 212, and 213 disposed on the temporary substrate 10. In addition, the first passivation layer 220 may be formed on the entire surface of the temporary substrate 10, or may be independently formed for each pixel P region composed of three micro LED chips 211, 212, and 213.

The first passivation layer 220 may be formed of an insulating material, for example, acryl, polymethylmethacrylate (PMMA), benzocyclobutene (BCB), polyimide, acrylate, epoxy, polyester, or the like. Preferably, the first passivation layer 220 may include a material capable of absorbing light, for example, a black matrix, and when the black matrix is applied, mixing of colors emitted through the temporary substrate 10 may be prevented.

In FIG. 30, a photoresist layer forming step is illustrated.

Referring to FIG. 30, in the forming of the photoresist layer, the photoresist layer PR is formed on the first passivation layer 220 on the micro LED chips 211, 212, and 213 so as to have an area larger than that of the micro LED chips 211, 212, and 213. The photoresist layer PR formed in the photoresist layer forming step has a structure in which an opening 225 penetrating vertically is formed in a central portion corresponding to the micro LED chips 211, 212, and 213 so that the surface of the first passivation layer 220 is exposed. In this case, the size of the opening 225 may be formed to be smaller than the size of the upper surfaces of the micro LED chips 211, 212, and 213 so that the first passivation layer 220 may partially exist on the edge of the upper surfaces of the micro LED chips 211, 212, and 213 when the upper surface of the first passivation layer 220 at the opening 225 side is etched and removed in a first etching step to be described later.

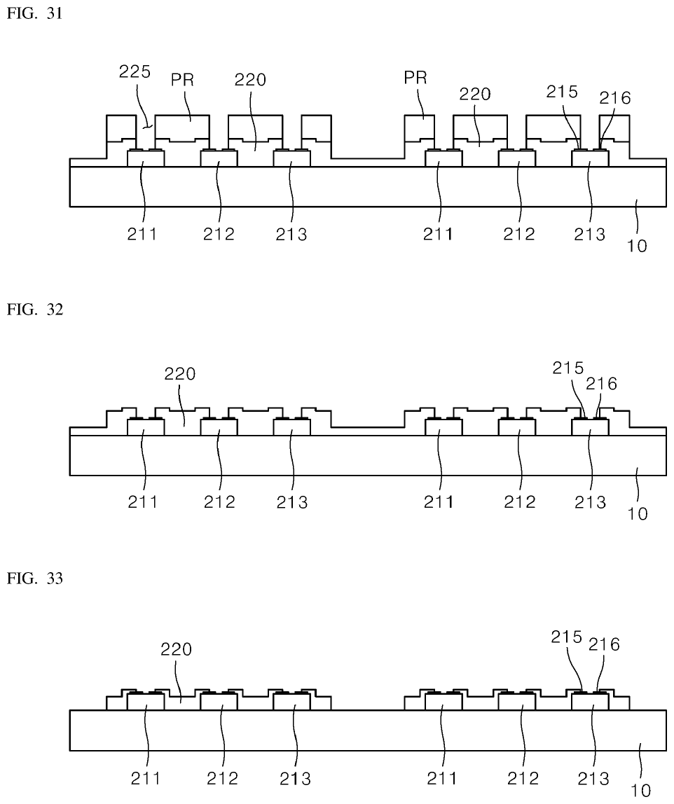

A first etching step is shown in FIG. 31.

Referring to FIG. 31, in the first etching step, a portion of the first passivation layer 220 is etched and removed. More specifically, in the first etching step, a central portion of the first passivation layer 220 corresponding to the opening portion 225 is removed to expose electrodes of the micro LED chips 211, 212, and 213 and a central portion of an upper surface thereof to the outside, and simultaneously, the first passivation layer 220 corresponding to the periphery of the pixel P, which is an edge region of the first passivation layer 220, is removed by a predetermined thickness to generate a step between the first passivation layer 220 corresponding to the pixel P region and the first passivation layer 220 peripheral the pixel P region. In the first etching step, a reactive ion etching (RIE) method may be applied.

In the step of removing the photoresist layer, after the first etching step, the photoresist layer PR on the first passivation layer 220 is removed so that the first passivation layer 220 is exposed as illustrated in FIG. 32. After the photoresist layer PR is removed, side surfaces and upper edge portions of the micro LED chips 211, 212, and 213 are partially surrounded by the first passivation layer 220, and electrodes and central portions of upper surfaces of the micro LED chips 211, 212, and 213 are exposed to the outside.

A second etching step is shown in FIG. 33.

Referring to FIG. 33, in the second etching step, the first passivation layer 220 remaining after the first etching step is etched to a predetermined thickness to reduce the height of the first passivation layer 220. In the second etching step, a reactive ion etching (RIE) method may be applied as applied in the first etching step.

In the second etching step, it is preferable to remove the first passivation layer 220 so that the first passivation layer 220 covering the edge portions of the upper surfaces of the micro LED chips 211, 212, and 213 may maintain the lowest height, without removing all of the first passivation layer 220 covering the edge portions of the upper surfaces of the micro LED chips 211, 212, and 213.

When all of the first passivation layer 220 surrounding the edge sides of the micro LED chips 211, 212, and 213 is removed in the second etching step, a phenomenon in which the first passivation layer and the side surfaces of the micro LED chips 211, 212, and 213 are spaced apart from each other near the interface between the side surfaces of the micro LED chips 211, 212, and 213 and the first passivation layer 220, is generated. Due to the phenomenon, the first wiring layer may be disconnected, therefore, it is preferable that all of the first passivation layer 220 surrounding the edge sides of the micro LED chips 211, 212, and 213 may not be removed in the second etching.

In the second etching step, after a portion of the first passivation layer 220 is removed, the height of the first passivation layer 220 remaining on the edge side of the upper surface of the micro LED chips 211, 212, and 213 may be formed slightly higher than the height of the electrode or the upper surface of the micro LED chips 211, 212, and 213.

In the second etching step, after a portion of the first passivation layer 220 is removed, the height of the first passivation layer 220 remaining on the edge side of the upper surface of the micro LED chips 211, 212, and 213 may be formed to have a thickness smaller than the thickness of a first wiring layer.

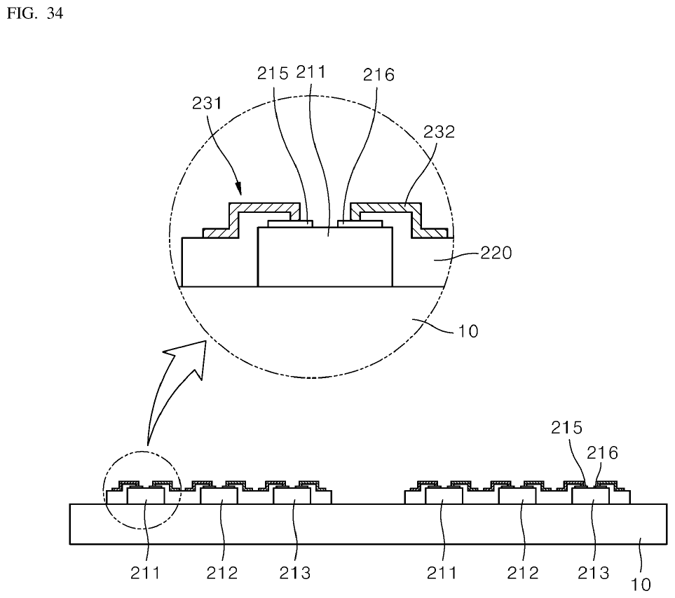

FIG. 34 illustrates a first wiring layer forming step.

Referring to FIG. 34, in the forming of the first wiring layer, after the second etching step is completed, the first wiring layer is formed to be inter-connected to each of the positive electrode 215 and the negative electrode 216 provided on the upper surfaces of the micro LED chips 211, 212, and 213.

The first wiring layer formed in the step of forming of the first wiring layer includes a first anode wiring layer 231 inter-connected to the positive electrode 215 of the micro LED chips 211, 212, and 213 and a first cathode wiring layer 232 inter-connected to the negative electrode 216 of the micro LED chips 211, 212, and 213.

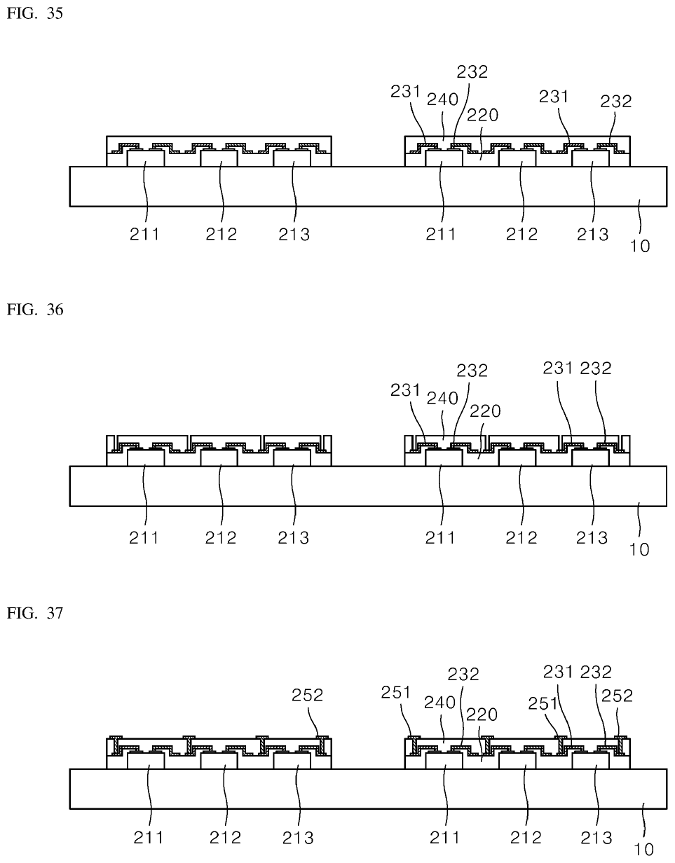

In the step of forming of the second passivation layer, as shown in FIG. 35, the second passivation layer 240 may be formed to have a predetermined thickness so as to surround the first passivation layer 220 and the first wiring layer together. Here, the second passivation layer 240 may be formed to entirely cover the first wiring layer. The second passivation layer 240 may be formed of, for example, acryl, poly (methyl methacrylate) (PMMA), benzocyclobutene (BCB), polyimide, acrylate, epoxy, polyester, or the like.

A third etching step is shown in FIG. 36.

Referring to FIG. 36, in the third etching step, a portion of the second passivation layer 240 is etched and removed so that a portion of the upper surface of the first wiring layer connected to the positive electrode and the negative electrode of the micro LED chips 211, 212, and 213, respectively, is exposed. In the third etching step, vertically penetrating holes are formed in a region of the second passivation layer 240 corresponding to an upper portion of the first wiring layer.

In FIG. 37, a step of forming a second wiring layer is illustrated.

Referring to FIG. 37, in the step of forming the second wiring layer, the second wiring layer is formed on the second passivation layer 240 to be electrically connected to the first wiring layer. The second wiring layer formed in the step of forming the second wiring layer is configured to include a conductive material and extends to be exposed to the surface of the second passivation layer 240 through the hole of the second passivation layer 240.

The second wiring layer may include a second anode wiring layer 251 and a second cathode wiring layer 252. The second anode wiring layer 251 may have one side inter-connected to the first anode wiring layer 231 and may penetrate through the hole of the second passivation layer 240 so that the other side thereof is exposed to the surface of the second passivation layer 240. One side of the second cathode wiring layer 252 is inter-connected to the first cathode wiring layer 232, and penetrates through the hole of the second passivation layer 240, and the other side thereof is exposed to the surface of the second passivation layer 240.

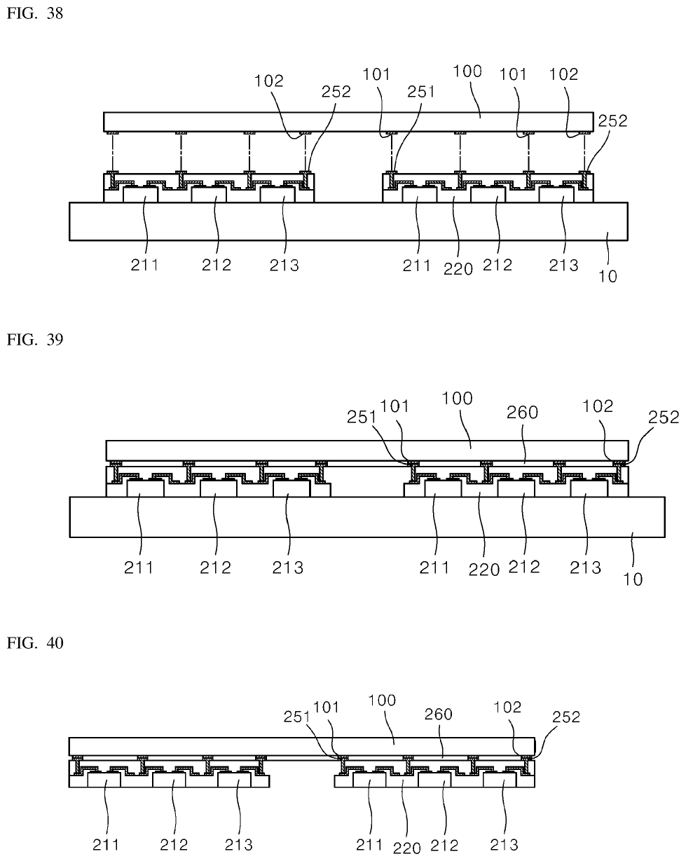

In FIG. 38, a second transferring step is illustrated.

Referring to FIG. 38, the second transferring step, which is a step of transferring only the packaged micro LED chips 211, 212, and 213 from the temporary substrate 10 onto the main substrate 100 functioning as a backplane, may include a connecting step and a separating step.

In the connection step, the main substrate 100 functioning as a backplane is electrically connected to the second wiring layer including the second anode wiring layer 251 and the second cathode wiring layer 252.

After the main substrate 100 is attached to the second wiring layer, an underfill process for filling a resin 60 between the second passivation layer 240 or the second wiring layer and the main substrate 100, may be performed, as illustrated in FIG. 39. After the underfill process is completed, the separation step is performed as shown in FIG. 40.

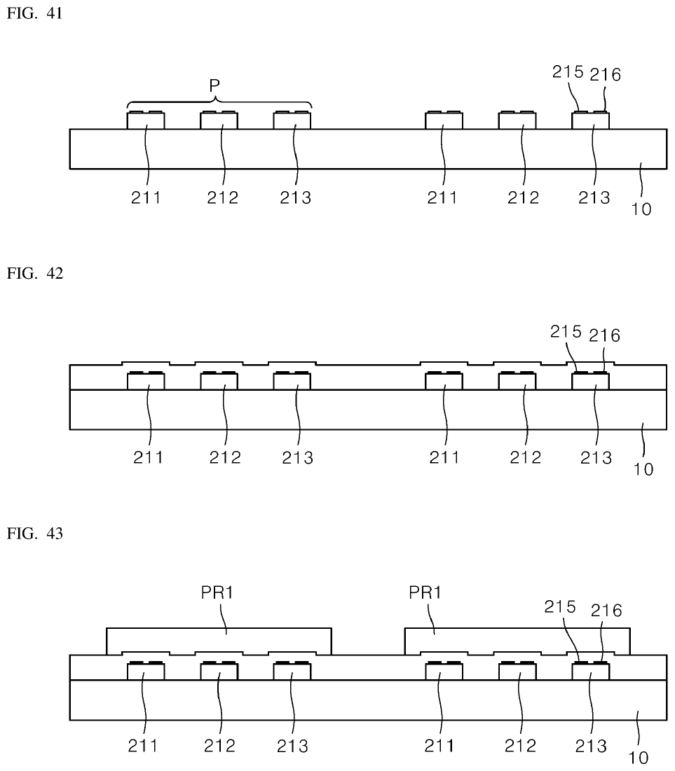

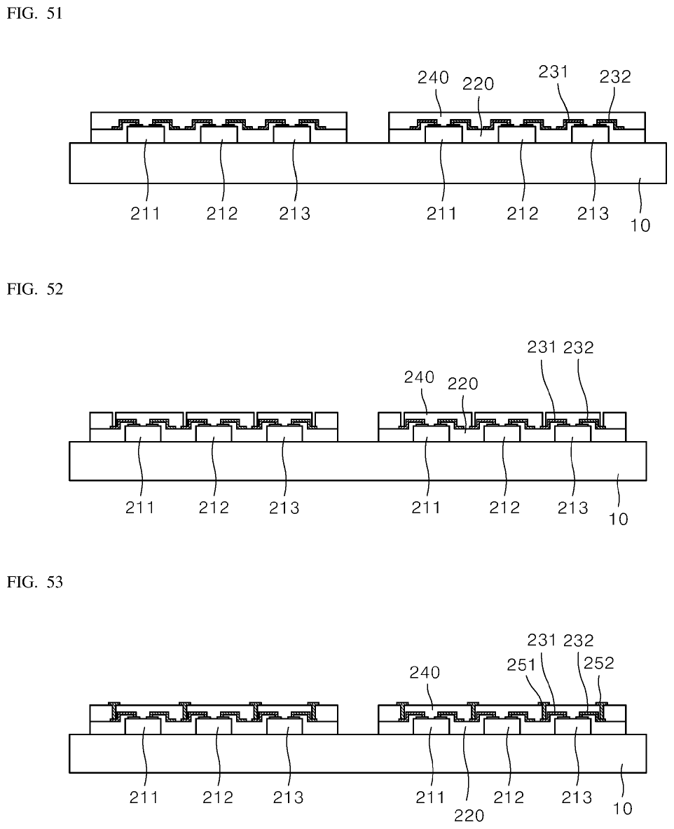

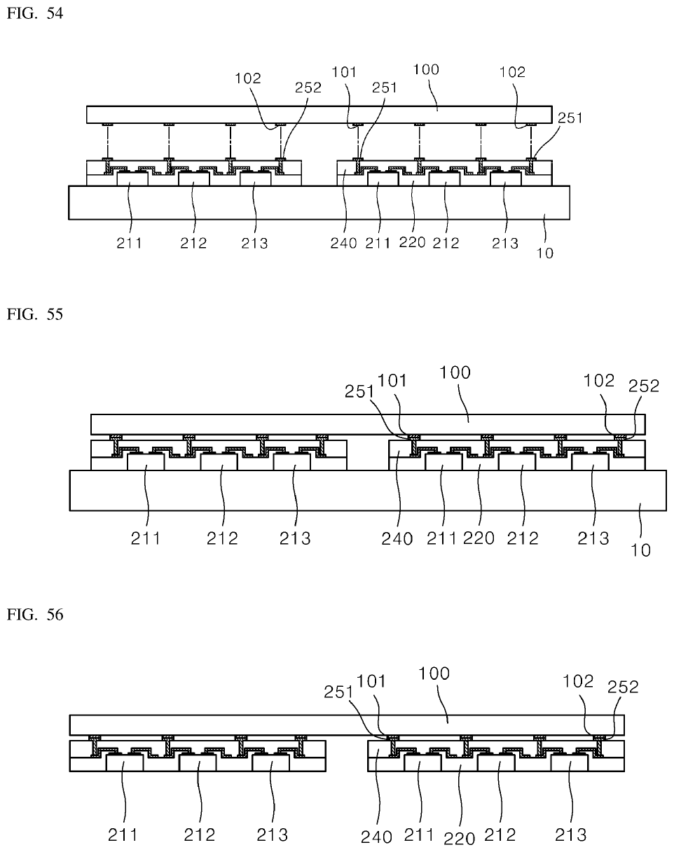

Meanwhile, FIGS. 41 to 56 illustrate a method of manufacturing a display according to another embodiment of the present invention. Referring to FIGS. 41 to 56, a method of manufacturing a display according to another embodiment of the present invention may include a first transferring step of transferring micro LED chips 211, 212, and 213 formed on a growth substrate to be disposed on one surface of a temporary substrate 10, an inspection step of inspecting the micro LED chips 211, 212, and 213 transferred to the temporary substrate 10, a replacement step of removing the defective micro LED chips selected in the inspection step from the temporary substrate 10 and replacing the defective micro LED chips with non-defective micro LED chips, a fixing step of fixing the micro LED chips on the temporary substrate 10 to the temporary substrate 10, a wiring step of forming a wiring portion on the micro LED chips fixed to the temporary substrate 10, and a second transferring step of transferring only the micro LED chips from the temporary substrate 10 to a main substrate 100 functioning as a backplane.

In the method of manufacturing a display according to another embodiment of the present invention, the same method as the method of manufacturing a display according to the embodiment described with reference to FIGS. 28 to 40 was applied for the first transferring step, the inspection step, the replacement step, the fixing step, and the second transfer step except the wiring step. Therefore, a repetitive description for the same method will be omitted.

The wiring step of this embodiment includes a first passivation layer forming step, a first photoresist layer forming step, a first etching step, a first photoresist layer removing step, a second photoresist layer forming step, a second etching step, a second photoresist removing step, a third etching step, a first wiring layer forming step, a second passivation layer forming step, a fourth etching step, and a second wiring layer forming step.

In the wiring step, the same method as the method of manufacturing a display according to the embodiment described with reference to FIGS. 28 to 40 was applied to the first passivation layer forming step, the first wiring layer forming step, and the second passivation layer forming step except for the first photoresist layer forming step, the first etching step, the first photoresist layer removing step, the second photoresist layer forming step, the second etching step, the second photoresist removing step, the third etching step. Therefore, a repetitive description for the same method will be omitted.

A first transferring step is illustrated in FIG. 41, a first passivation layer forming step is illustrated in FIG. 42, and a first photoresist layer forming step is illustrated in FIG. 43.

Referring to FIG. 43, in the first photoresist layer forming step, the first photoresist layer PR1 is formed on the first passivation layer 220 on the micro LED chips 211, 212, and 213 to have a larger area than the micro LED chips 211, 212, and 213. In this case, the first photoresist layer PR1 may be formed in a region corresponding to the first passivation layer 220, or alternatively, may be independently formed only in a portion corresponding to the pixel P region composed of the three micro LED chips 211, 212, and 213. Preferably, the first photoresist layer is independently formed only the portion corresponding to the pixel P region so that the first passivation layer 220 around the pixel P region is entirely removed in the first etching step and the second etching step in order that each pixel P region can be distinguished.

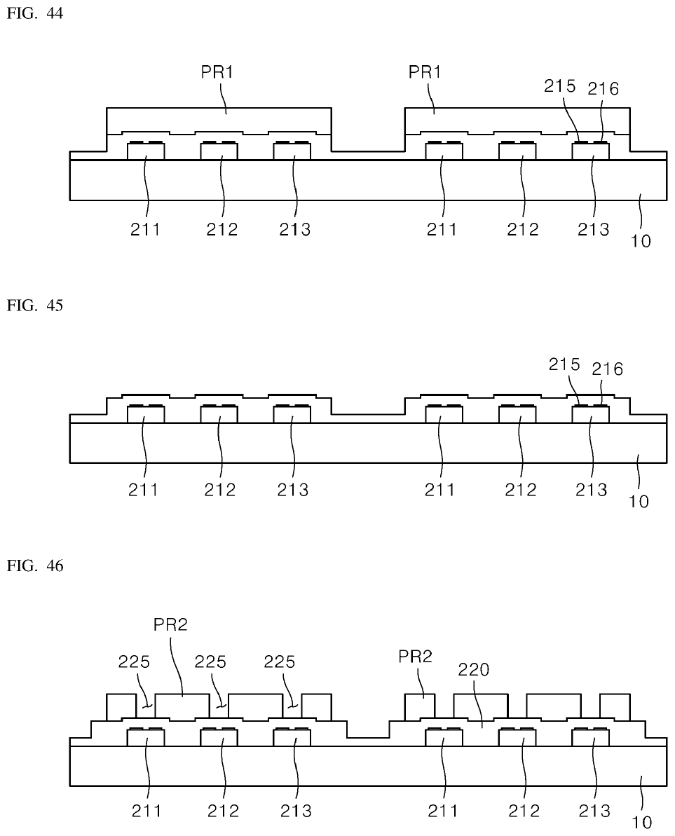

A first etching step is shown in FIG. 44.

Referring to FIG. 44, in the first etching step, a portion of the first passivation layer 220 is etched and removed. In more detail, in the first etching step, the first passivation layer 220 corresponding to the periphery of the pixel P region, which is an edge region of the first passivation layer 220, is removed by a predetermined thickness, so that a step is generated between the first passivation layer 220 corresponding to the pixel P region and the first passivation layer 220 peripheral area of the pixel P region. The first etching step may be performed by reactive ion etching (RIE).

In the first photoresist layer removing step, after the first etching step, the first photoresist layer PR1 on the first passivation layer 220 is removed so that the first passivation layer 220 is exposed, as shown in FIG. 45.

In FIG. 46, a second photoresist layer forming step is illustrated.

Referring to FIG. 46, in the forming of the second photoresist layer, the second photoresist layer PR2 is formed on the first passivation layer 220 on the micro LED chips 211, 212, and 213 so as to have an area larger than that of the micro LED chips 211, 212, and 213. The second photoresist layer PR2 formed in the step of forming the second photoresist layer 40 has a structure in which an opening 225 vertically penetrating is formed in a central portion corresponding to the micro LED chips 211, 212, and 213 so that the surface of the first passivation layer 220 is exposed, as shown in 46. In this case, the size of the opening 225 may be formed to be smaller than the size of the upper surfaces of the micro LED chips 211, 212, and 213 so that the first passivation layer 220 may partially exist on the edge of the upper surfaces of the micro LED chips 211, 212, and 213 when the upper surface of the first passivation layer 220 at the opening 225 side is etched and removed in a second etching step.

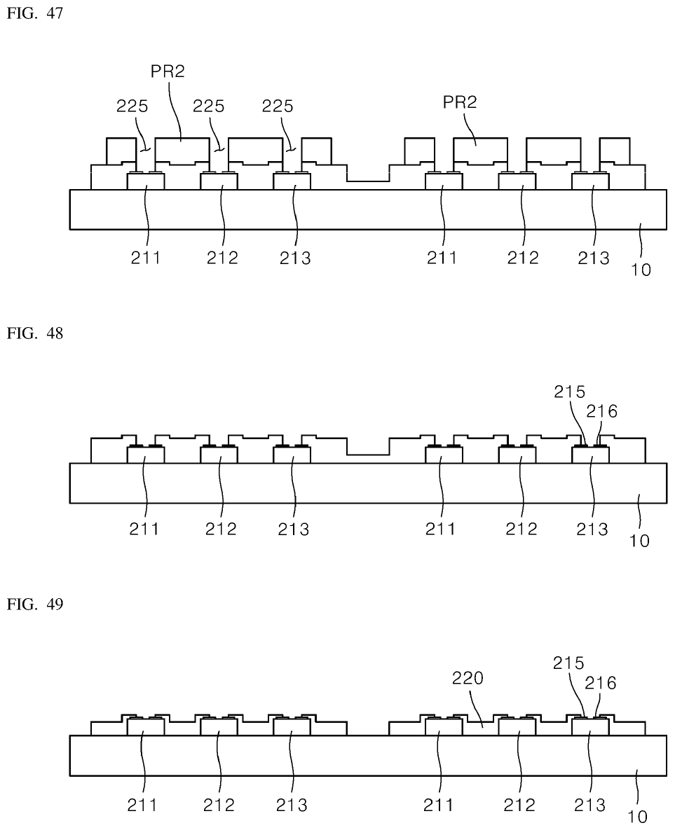

A second etching step is shown in FIG. 47.

Referring to FIG. 47, in the second etching step, a portion of the first passivation layer 220 is etched and removed. More specifically, in the second etching step, the central portion of the first passivation layer 220 corresponding to the opening portion 225 is removed to expose the electrodes of the micro LED chips 211, 212, and 213 and the central portion of the upper surface to the outside, and simultaneously, the first passivation layer 220 corresponding to the periphery of the pixel P, which is the edge region of the first passivation layer 220, is completely removed to distinguish regions between the pixels P. In the second etching step, a reactive ion etching (RIE) method may be applied as in the first etching step.

In the removing of the second photoresist layer PR2, after the second etching, the second photoresist layer PR2 on the first passivation layer 220 is removed so that the first passivation layer 220 is exposed, as shown in FIG. 48. After the second photoresist layer PR2 is removed, side surfaces and upper edge portions of the micro LED chips 211, 212, and 213 are partially surrounded by the first passivation layer 220, and electrodes and central portions of upper surfaces of the micro LED chips 211, 212, and 213 are exposed to the outside.

A third etching step is shown in FIG. 49.

Referring to FIG. 49, in the third etching step, the first passivation layer 220 remaining after the second etching step is etched to a predetermined thickness and removed so as to reduce the height of the first passivation layer 220. In the third etching step, a reactive ion etching (RIE) method may be applied as applied in the first etching step and the second etching step.

In the third etching, it is preferable to remove the first passivation layer 220 covering the edge portions of the upper surfaces of the micro LED chips 211, 212, and 213 so that the first passivation layer 220 covering the edge portions of the upper surfaces of the micro LED chips 211, 212, and 213 may be removed to maintain the lowest height.

If all of the first passivation layer 220 surrounding the edge sides of the micro LED chips 211, 212, and 213 is removed in the third etching step, a phenomenon in which the first passivation layer and the side surfaces of the micro LED chips 211, 212, and 213 are spaced apart from each other near the interface between the side surfaces of the micro LED chips 211, 212, and 213 and the first passivation layer 220, and thus, a phenomenon in which the first wiring layers 231 and 232 are disconnected occurs. Therefore, in the second etching, it is preferable that all of the first passivation layer 220 surrounding the edge sides of the micro LED chips 211, 212, and 213 is not removed.

In the third etching step, after a portion of the first passivation layer 220 is removed, the height of the first passivation layer 220 remaining on the edge side of the upper surface of the micro LED chips 211, 212, and 213 may be formed slightly higher than the height of the electrode or the upper surface of the micro LED chips 211, 212, and 213.

In the third etching step, after a portion of the first passivation layer 220 is removed, the height of the first passivation layer 220 remaining on the edge side of the upper surface of the micro LED chips 211, 212, and 213 may be formed to have a thickness smaller than the thickness of the first wiring layers 231 and 232.

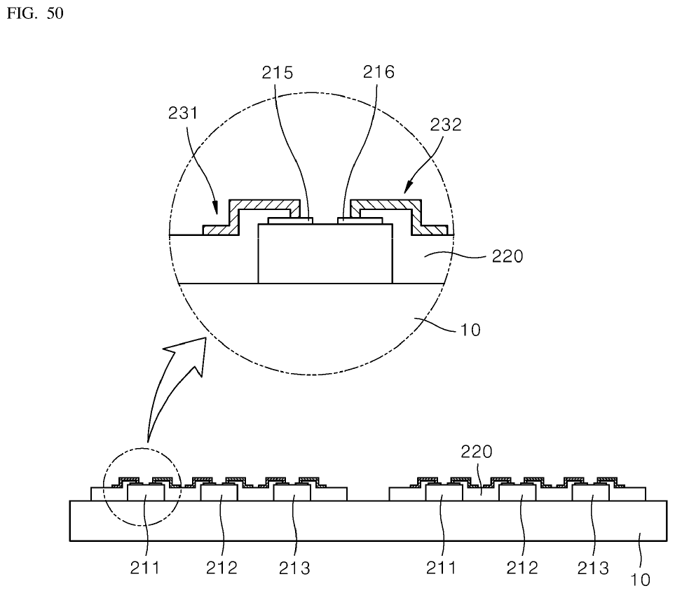

After the third etching step, as shown in FIGS. 50 to 56, a first wiring layer forming step, a second passivation layer 60 forming step, a fourth etching step, a second wiring layer forming step, a connection step, and an underfill process are sequentially performed.

Here, in the fourth etching step, a portion of the second passivation layer 60 is etched and removed so that portions of the upper surfaces of the first wiring layers 231 and 232 connected to the anode electrodes 215 and the cathode electrodes 216 of the micro LED chips 211, 212, and 213, respectively, are exposed, in the same manner as the third etching step of the method of manufacturing a display according to the embodiment of the present invention as shown in FIG. 36. In the fourth etching step, penetrating vertically holes are formed in regions of the second passivation layer 60 corresponding to upper portions of the first wiring layers 231 and 232.

The micro LED package, the display having the same, and the method for manufacturing the display according to the present invention described above have been described with reference to the accompanying drawings, but this is merely an example, and those skilled in the art will understand that various modifications and other equivalent embodiments are possible therefrom.

Therefore, the scope of the true technical protection of the present invention should be defined only by the technical spirit of the appended claims.

1. A micro LED package comprising:
a temporary substrate;
a plurality of micro LED chips arranged on the temporary substrate;
a first passivation layer formed to surround the micro LED chips;
a plurality of first wiring layers having one side connected to electrodes of each of the micro LED chips and the other side extending along the first passivation layer;
a second passivation layer formed to surround upper portions of the first wiring layers and between the first wiring layers; and
a plurality of second wiring layers having one side connected to the first wiring layer through the second passivation layer and the other side extending along the second passivation layer.

2. The micro LED package of claim 1, wherein the number of the second wiring layers is less than the total number of electrodes of the micro LED chips included in the micro LED package.

3. A display comprising:
a main substrate having a driving connection electrode unit provided on one surface thereof;
a plurality of micro LED packages mounted on the main substrate to constitute a single pixel or a plurality of pixels on the main substrate, the micro LED packages including a plurality of micro LED chips, rearranged wiring portions respectively connected to electrodes of the micro LED chips, and a passivation layer insulating the wiring portions; and
a connection relay unit connecting the wiring portions of the respective micro LED packages to the driving connection electrode unit,
wherein the micro LED packages are transferred onto the main substrate in a state in which the plurality of micro LED chips, the passivation layer, and the wiring portions are packaged on a temporary substrate.

4. The display of claim 3, wherein the micro LED package comprises:
a plurality of micro light emitting diode (LED) chips arranged to be spaced apart from each other at a predetermined distance in a horizontal direction;
a first passivation layer formed to surround the micro LED chips;
a plurality of first wiring layers each having one side connected to electrodes of each of the micro LED chips and the other side extending along the first passivation layer;
a second passivation layer formed to surround upper portions of the first wiring layers and between the first wiring layers; and
a plurality of second wiring layers each having one side connected to the first wiring layer through the second passivation layer and the other side extending along the second passivation layer.

5. The display of claim 4, wherein the first passivation layer is formed to have a height lower than one surface on which the electrode of the micro LED chip is formed, and
the first wiring layer comprises a first horizontal wiring portion extending to surround an upper surface of the first passivation layer, a vertical wiring portion extending from the first horizontal wiring portion around the micro LED chip to surround a side surface of the micro LED chip, and a second horizontal wiring portion extending from the vertical wiring portion to surround the upper surface and the electrode of the micro LED chip together.

6. The display of claim 4, wherein the first passivation layer comprises a first flat portion formed to have a height lower than one surface on which the electrode of the micro LED chip is formed, and a first protruded portion protruded so as to surround the electrode one surface of LED chips on which the electrodes are formed around the micro LED chips, and
the first wiring layer comprises a first horizontal wiring portion extending to surround an upper surface of the first flat portion, a first vertical wiring portion extending from the first horizontal wiring portion to surround a side surface of the first protruded portion, a second horizontal wiring portion extending from the first vertical wiring portion to surround an upper surface of the first protruded portion, and a second vertical wiring portion extending from the second horizontal wiring portion to surround an upper surface of the electrode of the micro LED chip.

7. The display of claim 4, wherein a black matrix is disposed on the first passivation layer.

8. The display of claim 4, wherein the number of the second wiring layers is less than the total number of the electrodes of the micro LED chips included in the micro LED package.

9. A method for manufacturing a display which comprises:
a first transferring step of transferring a micro LED chip formed on a growth substrate to be arranged on a first surface of a temporary substrate;
an inspecting step of inspecting the micro LED chip transferred on the temporary substrate;
a replacing step of removing a defective micro LED chip selected in the inspecting step from the temporary substrate and replacing the defective micro LED chip with a non-defective micro LED chip;
a fixing step of fixing the micro LED chip on the temporary substrate to the temporary substrate;
a wiring step of forming a wiring portions on the micro LED chip fixed on the temporary substrate; and
a second transferring step of transferring only the micro LED chip from the temporary substrate to a main substrate functioning as a backplane,
wherein the wiring step comprises:
a step of forming a first passivation layer to surround a first surface of the temporary substrate and the micro LED chip together;
a step of forming a photoresist layer on the first passivation layer on an upper side of the micro LED chip to have an area larger than that of the micro LED chip;
a step of performing a first etching process of etching and removing a portion of the first passivation layer;
a step of removing the photoresist layer;
a step of performing a second etching process of etching and removing a portion of the first passivation layer to expose an entire electrode and an upper surface of the micro LED chip to the outside;
a step of forming a first wiring layer to be electrically connected to the electrode of the micro LED chip;
a step of forming a second passivation layer on the first passivation layer and the first wiring layer;
a step of performing a third etching process of etching and removing a portion of the second passivation layer to expose a portion of an upper surface of the first wiring layer of the micro LED chip; and
a step of forming a second wiring layer to be electrically connected to the first wiring layer on the second passivation layer.

10. The method for manufacturing a display of claim 9, wherein the step of performing a second etching process comprises removing the first passivation layer such that a distance between an upper surface of the micro LED chip and an upper surface of the first passivation layer is smaller than a thickness of the first wiring layer to prevent the first wiring layer from being disconnected near an interface between the first passivation layer and the micro LED chip while the first passivation layer is deformed during curing process.

11. The method of manufacturing a display of claim 9, wherein the second wiring layer comprises a second anode wiring layer on the second passivation layer so as to be exposed and being connected to a first connection electrode of a main substrate, and a second cathode wiring layer on the second passivation layer so as to be exposed and being connected to a second connection electrode of the main substrate.

12. The method for manufacturing a display of claim 9, wherein the second transferring step comprises:
electrically connecting the main substrate functioning as a backplane to the second wiring layer; and
separating the micro LED chip and the first passivation layer from the temporary substrate after irradiating laser beams toward an interface between the temporary substrate and the micro LED chip and an interface between the temporary substrate and the first passivation layer for a predetermined time from the temporary substrate so as to weaken or release a bonding force between the micro LED chip and the temporary substrate.

13. A method for manufacturing a display comprises:
a first transferring step of transferring a micro LED chip formed on a growth substrate to be arranged on a first surface of a temporary substrate;
an inspecting step of inspecting the micro LED chip transferred on the temporary substrate;
a replacing step of removing a defective micro LED chip selected in the inspecting step from the temporary substrate and replacing the defective micro LED chip with a non-defective micro LED chip;
a fixing step of fixing the micro LED chip on the temporary substrate to the temporary substrate;
a wiring step of forming a wiring portions on the micro LED chip fixed on the temporary substrate; and
a second transferring step of transferring only the micro LED chip from the temporary substrate to a main substrate functioning as a backplane,
wherein the wiring step comprises:
a step of forming a first passivation layer to surround a first surface of the temporary substrate and the micro LED chip together;
a step of forming a photoresist layer on the first passivation layer on an upper side of the micro LED chip, the photoresist layer having an area larger than that of the micro LED chip and having an opening having an area smaller than that of an upper surface of the micro LED chip such that a surface of the first passivation layer is exposed in a central portion corresponding to the micro LED chip;
a step of performing a first etching process of etching and removing a portion of the first passivation layer to expose an electrode of the micro LED chip and a central portion of the upper surface thereof to the outside;
a step of removing the photoresist layer;
a step of performing a second etching process of etching and removing a portion of the first passivation layer;
a step of forming a first wiring layer to be electrically connected to the electrode of the micro LED chip;
a step of forming a second passivation layer on the first passivation layer and the first wiring layer;
a step of performing a third etching process of etching and removing a portion of the second passivation layer to expose a portion of an upper surface of the first wiring layer of the micro LED chip; and
a step of forming a second wiring layer to be electrically connected to the first wiring layer on the second passivation layer.

14. The method for manufacturing a display of claim 13, wherein the second etching step comprises removing the first passivation layer such that a distance between an upper surface of the micro LED chip and an upper surface of the first passivation layer is smaller than a thickness of the first wiring layer, to prevent the first wiring layer from being disconnected near an interface between the first passivation layer and the micro LED chip while the first passivation layer is deformed during curing process.

15. The method for manufacturing a display of claim 13, wherein the second wiring layer comprises a second anode wiring layer on the second passivation layer so as to be exposed and being connected to a first connection electrode of the main substrate, a second cathode wiring layer on the second passivation layer so as to be exposed and being connected to a second connection electrode of the main substrate.

16. The method for manufacturing a display of claim 13, wherein the second transferring step comprises:
electrically connecting the main substrate functioning as a backplane to the second wiring layer; and
separating the micro LED chip and the first passivation layer from the temporary substrate after irradiating laser beams toward an interface between the temporary substrate and the micro LED chip and an interface between the temporary substrate and the first passivation layer for a predetermined time from the temporary substrate so as to weaken or release a bonding force between the micro LED chip and the temporary substrate.

17. A method for manufacturing a display comprises:
a first transferring step of transferring a micro LED chip formed on a growth substrate to be arranged on a first surface of a temporary substrate;
an inspecting step of inspecting the micro LED chip transferred on the temporary substrate;
a replacing step of removing a defective micro LED chip selected in the inspecting step from the temporary substrate and replacing the defective micro LED chip with a non-defective micro LED chip;
a fixing step of fixing the micro LED chip on the temporary substrate to the temporary substrate;
a wiring step of forming wiring portions on the micro LED chip fixed on the temporary substrate; and
a second transferring step of transferring only the micro LED chip from the temporary substrate to a main substrate functioning as a backplane,
wherein the wiring step comprises:
a first passivation layer forming step of forming a first passivation layer to surround a first surface of a temporary substrate and the micro LED chip together;
a first photoresist layer forming step of forming a first photoresist layer on the first passivation layer on an upper side of the micro LED chip to have an area wider than that of the micro LED chip;
a first etching step of etching and removing a portion of the first passivation layer;
a first photoresist layer removing step of removing the first photoresist layer;
a second photoresist layer forming step of forming a second photoresist layer on the first passivation layer on an upper side of the micro LED chip, the second photoresist layer having an area larger than that of the micro LED chip and having an opening having an area smaller than that of an upper surface of the micro LED chip such that a surface of the first passivation layer is exposed in a central portion corresponding to the micro LED chip;
a second etching step of etching and removing a portion of the first passivation layer to expose an electrode and a central portion of an upper surface of the micro LED chip to the outside;
a second photoresist layer removing step of removing the second photoresist layer;
a third etching step of etching and removing a portion of the first passivation layer;
a first wiring layer forming step of forming a first wiring layer to be electrically connected to the electrode of the micro LED chip;
a second passivation layer forming step of forming a second passivation layer on the first passivation layer and the first wiring layer;
a fourth etching step of etching and removing a portion of the second passivation layer to expose a portion of an upper surface of the first wiring layer of the micro LED chip; and
a second wiring layer forming step of forming a second wiring layer to be electrically connected to the first wiring layer on the second passivation layer.

18. The method for manufacturing a display of claim 17, wherein the third etching step comprises removing the first passivation layer such that a distance between an upper surface of the micro LED chip and an upper surface of the first passivation layer is smaller than a thickness of the first wiring layer, to prevent the first wiring layer from being disconnected near an interface between the first passivation layer and the micro LED chip while the first passivation layer is deformed during curing.

19. The method for manufacturing a display of claim 17, wherein second wiring layer comprises a second anode wiring layer on the second passivation layer so as to be exposed and being connected to a first connection electrode of a main substrate, and a second cathoded wiring layer on the second passivation layer so as to be exposed and being connected to a second connection electrode of the main substrate.

20. The method for manufacturing a display of claim 17, wherein the second transferring step comprises:
electrically connecting a main substrate functioning as a backplane to the second wiring layer; and
separating the micro LED chip and the first passivation layer from the temporary substrate after irradiating laser beams toward an interface between the temporary substrate and the micro LED chip and an interface between the temporary substrate and the first passivation layer for a predetermined time from the temporary substrate so as to weaken or release a bonding force between the micro LED chip and the temporary substrate.
